(19) United States
(12) Patent Application Publication
(10) Pub. No.: US 2023/0402101 A1
(43) Pub. Date: Dec. 14, 2023

(54) TECHNIQUES FOR DETERMINING LAST PROGRAMMED WORDLINE

(71) Applicant: SanDisk Technologies LLC, Addison, TX (US)

(72) Inventors: KIRUBAKARAN PERIYANNAN, Saratoga, CA (US); DANIEL J. LINNEN, Naperville, IL (US); JAYAVEL PACHAMUTHU, San Jose, CA (US)

(21) Appl. No.: 17/835,396

(22) Filed: Jun. 8, 2022

(51) Int. Cl. G11C 16/10; G11C 16/16; G11C 16/26; G11C 16/08; G11C 16/24

(52) U.S. Cl. CPC G11C 16/102; G11C 16/16; G11C 16/26; G11C 16/08; G11C 16/24

(57) ABSTRACT

Embodiments of the present disclosure generally include methods of specially programming a set of memory cells, wherein each specially programmed memory cell is specially programmed along with programming a plurality of wordlines, and wherein each memory cell is specially programmed by altering a bitline and gate voltage applied to the memory cell. The methods further includes performing a sensing operation across a set of strings in the array of memory cells, determining, based on the sensing operation, whether one or more strings failed to conduct during a sensing operation, and determining the last programmed wordline using the one or more strings that failed to conduct.

### BACKGROUND

Flash memory is an electronic, non-volatile computer memory storage medium that can be electrically erased and reprogrammed. Flash memory is widely used across a range of products and industries including computers, mobile phones, tablet devices, personal digital assistants (PDAs), digital audio players, digital cameras, video games, scientific instrumentation, industrial robotics, and medical electronics, to name a few. NAND flash memory—one of the two primary types of flash memory—can be found in memory cards, USB flash drives, solid-state drives, smartphones, and the like. NAND flash may employ floating gate transistors, such as floating gate metal-oxide-semiconductor field-effect transistors (MOSFETs), connected in a manner that resembles a NAND logic gate to store a charge which represents a data state.

Charge-trapping material can be arranged vertically in a three-dimensional (3D) stacked memory structure. One example of a 3D stacked memory structure is the Bit Cost Scalable (BiCS) architecture which comprises a stack of alternating conductive and dielectric layers. A memory hole may be formed through the stack and a NAND string may then be formed by filling the memory hole with materials including a charge trapping layer to create a vertical column of memory cells. In an implementation, a straight NAND string extends in one memory hole. Control gates of the memory cells may be provided by the conductive layers.

Some non-volatile memory devices are used to store two ranges of charges, and can be programmed/erased between two ranges of threshold voltages that correspond to two data states. For example, an erased state (e.g., data “1”) and a programmed state (e.g., data “0”). Such a device is referred to as a binary or two-state device.

A multi-state non-volatile memory is implemented by identifying multiple, distinct allowed ranges of threshold voltages. Each distinct range of threshold voltages corresponds to a data state assigned a predetermined value for the set of data bits. The specific relationship between the data programmed into the memory cell and the ranges of threshold voltages depend upon the data encoding scheme adopted from the memory cells.

In some cases, when power is lost, a memory block may be left open depending on the point where programming was halted by the power loss. To begin programming of the open memory block again, a determination may be made as to where the programming halted. Existing techniques for making this determination suffer from various technical drawbacks.

### BRIEF DESCRIPTION OF THE DRAWINGS

The present disclosure, in accordance with one or more various embodiments, is described in detail with reference to the following figures. The figures are provided for purposes of illustration only and merely depict typical or example embodiments.

FIG. 1 is a block diagram of an example memory device, in connection with which, example embodiments of the disclosed technology can be implemented.

FIG. 2 is a block diagram of an example memory system, in connection with which, example embodiments of the disclosed technology can be implemented.

FIG. 3 is a perspective view of a portion of an example monolithic three-dimensional memory structure, in connection with which, example embodiments of the disclosed technology can be implemented.

FIG. 4A is a block diagram of an example memory structure having two planes, in connection with which, example embodiments of the disclosed technology can be implemented.

FIG. 4B depicts a top view of a portion of a block of example memory cells, in connection with which, example embodiments of the disclosed technology can be implemented.

FIG. 4C depicts a stack showing a cross-sectional view along line AA of FIG. 4B.

FIG. 4D depicts an alternative view of the select gate layers and wordline layers.

FIG. 4E depicts a view of the region 445 of FIG. 4C.

FIG. 4F is a schematic of a plurality of example NAND strings showing multiple horizontal sub-blocks, in connection with which, example embodiments of the disclosed technology can be implemented.

FIG. 4G is a schematic of horizontal sub-block HSB0.

FIG. 5 is a schematic block diagram depicting an example configuration of a sense block of memory die, in connection with which, example embodiments of the disclosed technology can be implemented.

FIG. 6A is an illustration of an example of a plurality of specially programmed memory cells, according to one embodiment.

FIG. 6B is an illustration of an example of a plurality of specially programmed memory cells, according to one embodiment.

FIG. 6C is an illustration of an example of a plurality of specially programmed memory cells, according to one embodiment.

FIG. 6D is an illustration of an example of a plurality of specially programmed memory cells, according to one embodiment.

FIG. 7A is an illustration of an example of a plurality of specially programmed memory cells programmed according to an independent plane scheme.

FIG. 7B is an illustration of an example of a plurality of specially programmed memory cells programmed according to an linked plane scheme.

FIG. 7C is an illustration of an example of a plurality of specially programmed memory cells.

FIG. 8 depicts a method of using the wordline tracking system, according to one embodiment.

The figures are not exhaustive and do not limit the present disclosure to the precise form disclosed.

### DETAILED DESCRIPTION

During a programming operation, blocks of memory cells are programmed according to a wordline programming order. However, sometimes the programming operation is interrupted and sets of memory cells are left partially or completely unprogrammed. Partially or completely unprogrammed memory cells can lead to read disturb errors.

One method of locating the partially programmed memory cells is conducting a time-intensive binary search through each column of a failing block to locate the wordline containing partially programmed memory cells. Repeated binary searches not only take time, but can also decrease the reliability of the memory cells, as each repeated search increases the chance that the array of cells within the block may be disrupted. Furthermore, as block sizes increase and cell geometries decrease, binary searches become less efficient since the larger the block, the more reads we have to do in the search process. However, by programming readily available unused redundant memory cells, to create specially programmed memory cells, the sensing block is able to determine the last programmed wordline without requiring a lengthy binary search.

In typical programming operations, programmed blocks contain columns of unused redundant memory cells since programming does not always require programming every memory cell in a wordline. Columns of these unused redundant memory cells can be programmed such that the progress of the programming operation can be tracked. Thus, when programming is interrupted, a sense block can be used to quickly and accurately determine the last programmed wordline. For example, in one embodiment, the unused redundant memory cells can be programmed such that a string sense operation or an erase verify operation can be used to track the last programmed wordline. Specifically, in one embodiment, programming one or more memory cells to create specially programmed memory cells includes adjusting the bitline and gate voltages applied to a transistor to alter the threshold voltage of the memory cell. By altering the threshold voltage of the memory cell, the voltage applied to the gate may not exceed the threshold voltage, therefore preventing the transistor from conducting. The string sense and erase verify operations can then be used to apply a voltage to each gate to determine the non-conducting string(s) associated with the specially programmed memory cell(s). As each new wordline is programmed, an additional memory cell is programmed to create an additional specially programmed memory cell in the unused redundant memory cells. Thus, the sense block can track the progress of the programming operation by tracking/counting the number of non-conducting strings. In one embodiment, the sense block can track the progress of the programming operation by tracking/counting the number of 0's. Furthermore, in yet another embodiment, the sense block can track the progress of the programming operation by tracking/counting the number of 1's.

For example, in one configuration, specially programmed cells are programmed such that the threshold voltage of the gate is higher than the voltage applied to the gate during a string sense operation or erase verify operation. For example, in one embodiment, a specially programmed cell may be programmed such that the threshold voltage of the transistor is altered to be about 0.3V. When a erase verify operation applies a voltage of about 0V to the gate, the transistor will not turn on and thus fail to conduct, resulting in the sensing circuit returning a value of 0. In another embodiment, for example, a specially programmed cell may be programmed such that the threshold voltage of the transistor is altered to about 1.3V. When a string sense operation applied a voltage of 1V to the gate, the transistor will not turn on, and thus fail to conduct, resulting in the sensing circuit returning a value of 0. Thus, the number of 1s or 0s can be counted to determine the last programmed wordline. It should be understood that the threshold values of specially programmed unused redundant memory cells can vary, so long as a distinction can be made between programmed (and erased) and unprogrammed unused redundant memory cells. For example, in one embodiment, the threshold voltage includes a threshold voltage used for string sensing that is slightly higher than the threshold voltage used for the erase verify. Furthermore, although a typical programming operation is used to create specially programmed memory cells, it is foreseeable that in an alternative embodiment, a specific programming operation to specially program each memory cell to create specially programmed memory cells can be used in place of the typical programming operation for programming user memory cells.

The expanding pyramidal structure of the specially programmed memory cells creates a matrix that can be used to track the last programmed wordline. For example, if programming was interrupted during the programming of a first wordline in a three wordline memory block, a string sense or erase verify operation could be run to determine the last programmed wordline. Since each memory cell of each wordline is associated with a string, the string sense or erase verify operation can apply a voltage to each gate of each memory cells within the string to determine which memory cells conduct. Since programming stopped during programming of the first wordline, only one unused redundant memory cell would be specially programmed. Thus, the string associated with the first specially programmed memory cell would fail to conduct and return one value of 0 at the sense block. Furthermore, if programming was interrupted during programming of a second wordline, the second wordline would include two specially programmed cells. Thus, each string associated with each specially programmed memory cell would fail to conduct, returning two values of 0 at the sense block. Moreover, if programming was interrupted during programming of a third wordline, the third wordline would include three specially programmed cells. Thus, each string associated with the specially programmed memory cell would fail to conduct, returning three values of 0 at the sense block. These values can be stored in the latching circuit, and counted to determine the last programmed wordline.

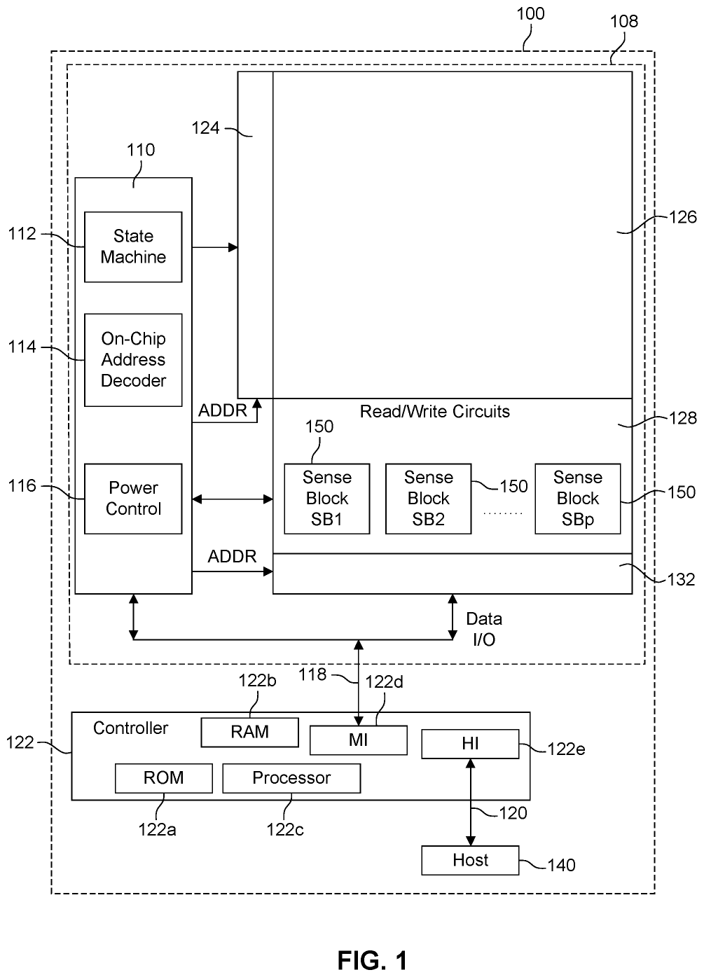

FIG. 1 is a block diagram of an example non-volatile memory system 100. In one embodiment, the non-volatile memory system 100 is a card-based system, such as a secure digital (SD) or a micro secure digital (micro-SD) card. In an alternate embodiment, memory system 100 is part of an embedded memory system. For example, the flash memory may be embedded within the host. In other examples, memory system 100 can be a solid state drive (SSD). The non-volatile memory system 100 includes one or more non-volatile memory dies 108, and a controller 122. The memory die 108 can be a complete memory die or a partial memory die. As seen here, the memory die 108 includes a memory structure 126, control circuitry 110, and read/write/erase circuits 128. The memory structure 126 is addressable by wordlines via a row decoder 124 and by bitlines via a column decoder 132. The read/write/erase circuits 128 include multiple sense blocks 150 including SB1, SB2, . . . , SBp (hereinafter referred to as sensing circuitry). The read/write/erase circuits 128 and sensing circuitry allow a page of memory cells to be read, programmed, or erased in parallel.

In one embodiment, memory structure 126 comprises a three-dimensional (3D) memory array of non-volatile memory cells in which multiple memory levels are formed above a single substrate, such as a wafer. The memory structure may comprise any type of non-volatile memory monolithically formed in one or more physical levels of arrays of memory cells having an active area disposed above a silicon (or other type of) substrate. In one example, the non-volatile memory cells comprise vertical NAND strings with charge-trapping material. In another embodiment, memory structure 126 comprises a two-dimensional (2D) memory array of non-volatile memory cells. In one example, the non-volatile memory cells are NAND flash memory cells utilizing floating gates.

The exact type of memory array architecture or memory cell included in memory structure 126 is not limited to the examples above. Many different types of memory array architectures or memory technologies can be used to form memory structure 126. No particular non-volatile memory technology is required for purposes of the new claimed embodiments proposed herein. Other examples of suitable technologies for memory cells of the memory structure 126 include 2D arrays, 3D arrays, and other memory structures that may have a string configuration. Although current iterations of other memory structure (e.g., MRAM, PCM, and Spin RAM) are configured without a string, memories of these cells can be configured into a topology that has a string, and thus could be utilized in a format that would allow them to be erased in a block format and programmed in chunks. Thus, in this potential configuration, embodiments of the disclosure could be foreseeably applied.

A person of ordinary skill in the art will recognize that the technology described herein is not limited to a single specific memory structure, but covers many relevant memory structures within the spirit and scope of the technology as described herein and as understood by one of ordinary skill in the art.

The control circuitry 110 cooperates with the read/write/erase circuits 128 to perform memory operations (e.g., write, read, erase) on memory structure 126, and includes state machine 112, an on-chip address decoder 114, and a power control circuit 116. In one embodiment, control circuitry 110 includes buffers such as registers, read-only memory (ROM) fuses and other storage devices for storing default values such as base voltages and other parameters. The on-chip address decoder 114 provides an address interface between addresses used by host 140 or controller 122 and the hardware address used by the decoders 124 and 132. Power control circuit 116 controls the power and voltages supplied to the wordlines, bitlines, and select lines during memory operations. The power control circuit 116 includes voltage circuitry, in one embodiment. Power control circuit 116 may include charge pumps for creating voltages. The sense blocks 150 include bitline drivers. The power control circuit 116 executes under control of the state machine 112, in one embodiment.

State machine 112 and/or controller 122 (or equivalently functioned circuits), in combination with all or a subset of the other circuits depicted in FIG. 1, can be considered a control circuit that performs the functions described herein. Such a control circuit can include hardware only or a combination of hardware and software (including firmware). For example, a controller programmed by firmware to perform the functions described herein is one example of a control circuit. A control circuit can include a processor, a PGA (Programmable Gate Array), an FPGA (Field Programmable Gate Array), an ASIC (Application Specific Integrated Circuit), or another type of integrated circuit or circuit more generally.

The controller 122 interfaces with the one or more memory dies 108. In one embodiment, controller 122 and multiple memory dies (together comprising non-volatile storage system 100) implement an SSD, which can emulate, replace, or be used in place of a hard disk drive inside a host, as a network access storage (NAS) device, in a laptop, in a tablet, in a server, etc. Additionally, the SSD need not be made to work as a hard drive.

Some embodiments of the non-volatile storage system 100 may include one memory die 108 connected to one controller 122. Other embodiments may include multiple memory dies 108 in communication with one or more controllers 122. In one example, the multiple memory dies 108 can be grouped into a set of memory packages. Each memory package may include one or more memory dies 108 in communication with controller 122. In one embodiment, a memory package includes a printed circuit board (or similar structure) with one or more memory dies 108 mounted thereon. In some embodiments, a memory package can include molding material to encase the memory dies 108 of the memory package. In some embodiments, controller 122 is physically separate from any of the memory packages.

In one embodiment, a controller 122 is included in the same package (e.g., a removable storage card) as the memory die 108. In other embodiments, the controller is separated from the memory die 108. In some embodiments the controller is on a different die than the memory die 108. In some embodiments, one controller 122 communicates with multiple memory dies 108. In other embodiments, each memory die 108 has its own controller. Commands and data are transferred between a host 140 and controller 122 via a data bus 120, and between controller 122 and the memory die 108 via lines 118. In one embodiment, memory die 108 includes a set of input and/or output (I/O) pins that connect to lines 118.

The controller 122 includes one or more processors 122c, ROM 122a, random access memory (RAM) 122b, a memory interface (MI) 122d, and a host interface (HI) 122e, all of which may be interconnected. The storage devices (ROM 122a, RAM 122b) store code (software) such as a set of instructions (including firmware), and one or more of the processors 122c are operable to execute the set of instructions to provide functionality described herein. Alternatively or additionally, one or more processors 122c can access code from a storage device in the memory structure, such as a reserved area of memory cells connected to one or more wordlines. RAM 122b can be used to store data for controller 122, including caching program data (discussed below). MI 122d—in communication with ROM 122a, RAM 122b, and processor(s) 122c—may be an electrical circuit that provides an electrical interface between controller 122 and memory die 108. For example, MI 122d can change the format or timing of signals, provide a buffer, isolate from surges, latch I/O, etc. One or more processors 122c can issue commands to control circuitry 110 (or another component of memory die 108) via MI 122d. Host interface 122e provides an electrical interface with host 140 via data bus 120 in order to receive commands, addresses and/or data from host 140 to provide data and/or status to host 140.

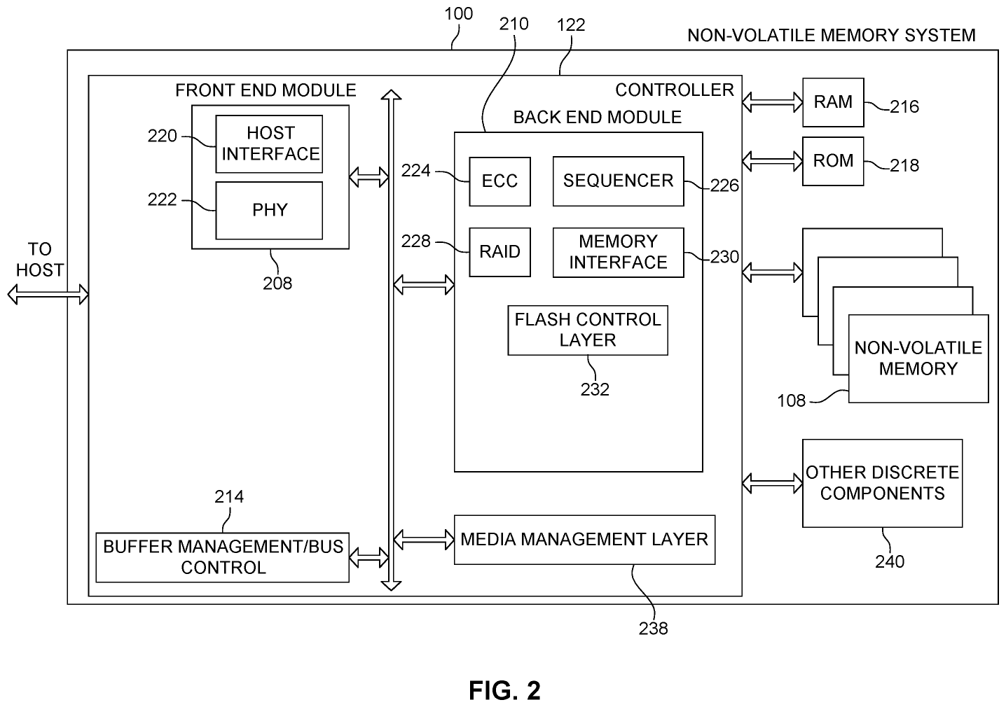

FIG. 2 is a block diagram of example memory system 100 that depicts more details of one embodiment of controller 122. While the controller 122 in the embodiment of FIG. 2 is a flash memory controller, it should be appreciated that the one or more non-volatile memory dies 108 are not limited to flash memory. Thus, the controller 122 is not limited to the particular example of a flash memory controller. As used herein, a flash memory controller is a device that manages data stored on flash memory and communicates with a host, such as a computer or electronic device. A flash memory controller can have various functionality in addition to the specific functionality described herein. For example, the flash memory controller can format the flash memory to ensure the memory is operating properly, map out bad flash memory cells, and allocate spare memory cells to be substituted for future failed cells. Some part of the spare cells can be used to hold firmware to operate the flash memory controller and implement other features. In an example operation, when a host needs to read data from or write data to the flash memory, it will communicate with the flash memory controller. If the host provides a logical address to which data is to be read/written, the flash memory controller can convert the logical address received from the host to a physical address in the flash memory. Alternatively, the host itself can provide the physical address. The flash memory controller can also perform various memory management functions including, but not limited to, wear leveling (distributing writes to avoid wearing out specific blocks of memory that would otherwise be repeatedly written to) and garbage collection (after a block is full, moving only the valid pages of data to a new block, so that the block can be erased and reused).

In some embodiments, non-volatile memory system 100 includes a single channel between controller 122 and non-volatile memory die 108. However, the subject matter described herein is not limited to having a single memory channel. For example, in some memory system architectures, 2, 4, 8 or more channels may exist between the controller and the memory die, depending on controller capabilities. In any of the embodiments described herein, more than a single channel may exist between the controller and the memory die, even if only a single channel is shown in the drawings.

As depicted in FIG. 2, controller 122 includes a front-end module 208 that interfaces with a host, a back-end module 210 that interfaces with the memory die 108, and various other modules that perform functions which will now be described in detail. The components of controller 122 depicted in FIG. 2 may take various forms including, without limitation, a packaged functional hardware unit (e.g., an electrical circuit) designed for use with other components, a portion of a program code (e.g., software or firmware) executable by a (micro) processor or processing circuitry that usually performs a particular function of related functions, a self-contained hardware or software component that interfaces with a larger system, or the like. For example, each module may include an ASIC, an FPGA, a circuit, a digital logic circuit, an analog circuit, a combination of discrete circuits, gates, or any other type of hardware or combination thereof. Alternatively or additionally, each module may include software stored in a processor readable device (e.g., memory) to program a processor to enable controller 122 to perform the functions described herein. The architecture depicted in FIG. 2 is one example implementation that may (or may not) use the components of controller 122 depicted in FIG. 1 (e.g., RAM, ROM, processor, interface).

Referring again to modules of the controller 122, a buffer manager/bus control 214 manages buffers in RAM 216 and controls the internal bus arbitration of controller 122. ROM 218 stores system boot code. Although illustrated in FIG. 2 as located separately from the controller 122, in other embodiments, one or both of RAM 216 and ROM 218 may be located within the controller. In yet other embodiments, portions of RAM 216 and ROM 218 may be located within the controller 122, while other portions may be located outside the controller. Further, in some implementations, the controller 122, RAM 216, and ROM 218 may be located on separate semiconductor dies.

Front-end module 208 includes a host interface 220 and a physical layer interface (PHY) 222 that provide the electrical interface with the host or next level storage controller. The choice of the type of host interface 220 can depend on the type of memory being used. Examples of host interfaces 220 include, but are not limited to, SATA, SATA Express, SAS, Fibre Channel, USB, PCIe, and NVMe. The host interface 220 typically facilitates transfer for data, control signals, and timing signals.

Back-end module 210 includes an error correction code (ECC) engine 224 that encodes the data bytes received from the host, and decodes and error corrects the data bytes read from the non-volatile memory 108. A command sequencer 226 generates command sequences, such as program and erase command sequences, to be transmitted to non-volatile memory 108. A RAID (Redundant Array of Independent Dies) module 228 manages generation of RAID parity and recovery of failed data. The RAID parity may be used as an additional level of integrity protection for the data being written into the non-volatile memory system 100. In some cases, the RAID module 228 may be a part of the ECC engine 224. Note that the RAID parity may be added as one or more extra dies, or may be added within the existing die, e.g., as an extra plane, an extra block, or extra WLs within a block. A memory interface 230 provides the command sequences to non-volatile memory die 108 and receives status information from non-volatile memory die 108. In one embodiment, memory interface 230 may be a double data rate (DDR) interface, such as a Toggle Mode 200, 400, or greater interface. A flash control layer 232 controls the overall operation of back-end module 210.

Additional components of system 100 illustrated in FIG. 2 include media management layer (MML) 238, which performs wear leveling of memory cells of non-volatile memory die 108, as well as, other discrete components 240, such as external electrical interfaces, external RAM, resistors, capacitors, or other components that may interface with controller 122. In alternative embodiments, one or more of the physical layer interface 222, RAID module 228, MML 238, or buffer management/bus controller 214 are optional components.

MML 238 (e.g., Flash Translation Layer (FTL)) may be integrated as part of the flash management for handling flash errors and interfacing with the host. In particular, MML 238 may be a module in flash management and may be responsible for the internals of NAND management. In particular, MML 238 may include an algorithm in the memory device firmware which translates writes from the host into writes to the memory 126 of die 108. MML 238 may be needed because: 1) the memory 126 may have limited endurance; 2) the memory 126 may only be written in multiples of pages; and/or 3) the memory 126 may not be written unless it is erased as a block (or a tier within a block in some embodiments). MML 238 understands these potential limitations of the memory 126 which may not be visible to the host. Accordingly, MML 238 attempts to translate the writes from host into writes into the memory 126.

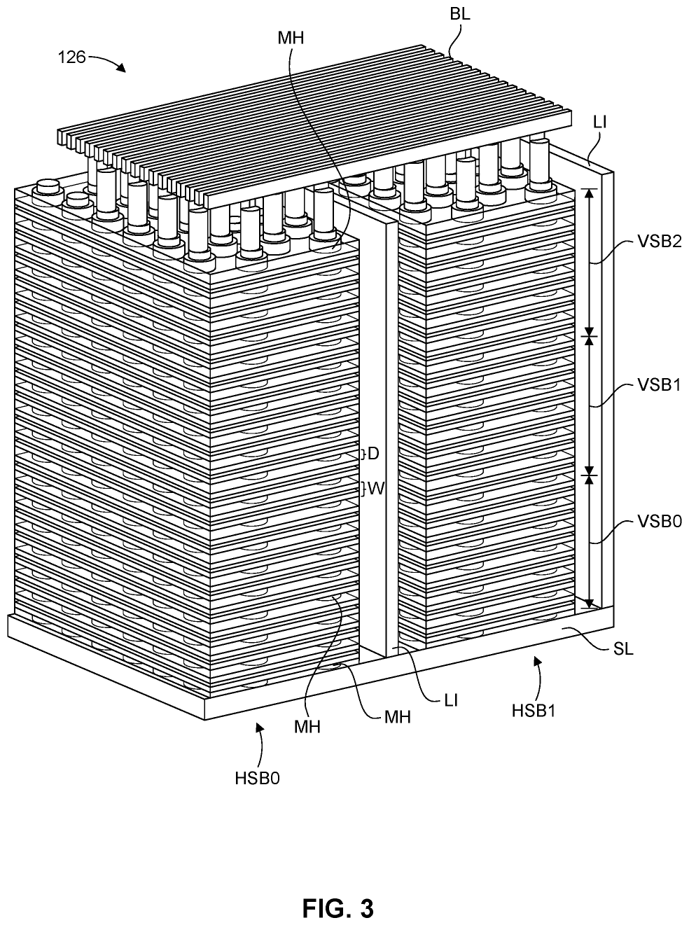

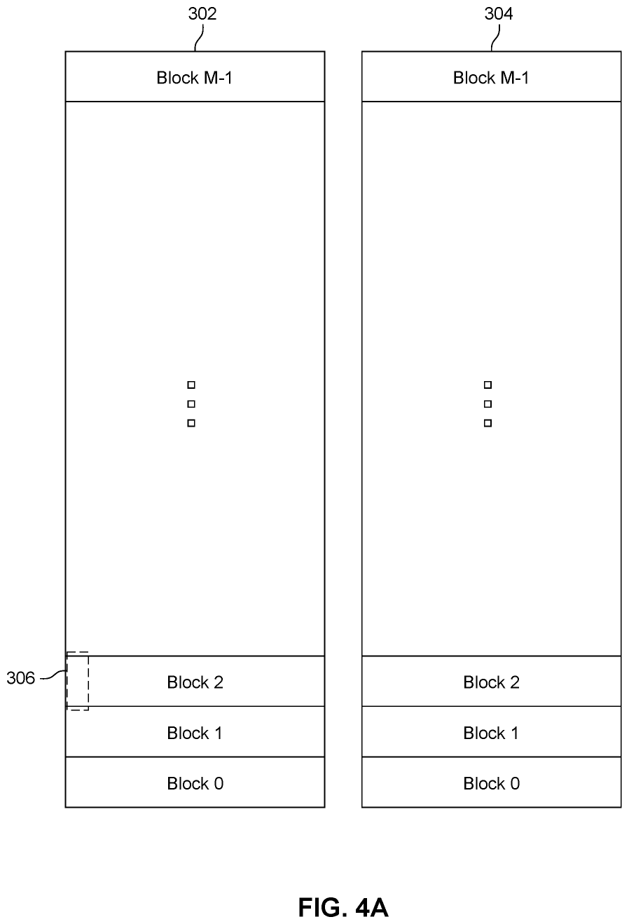

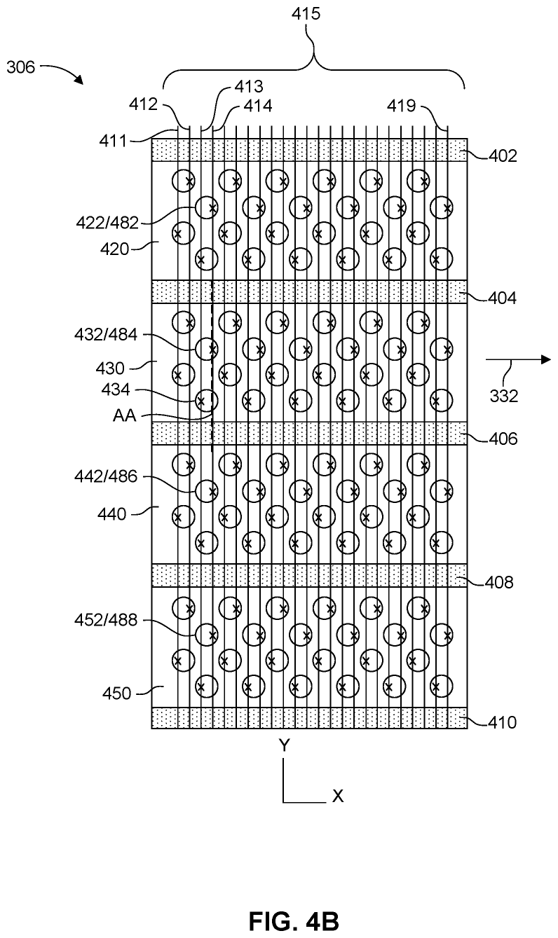

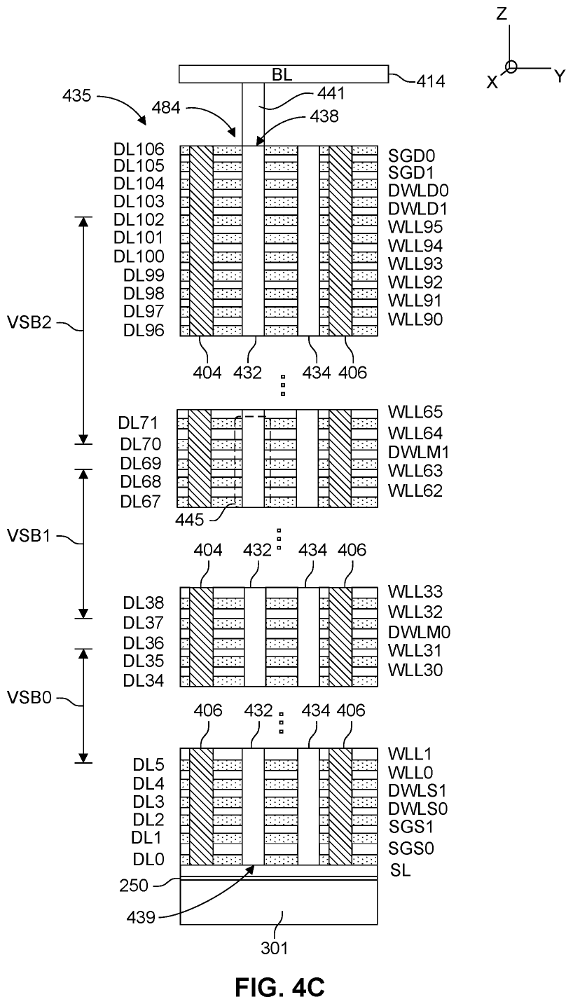

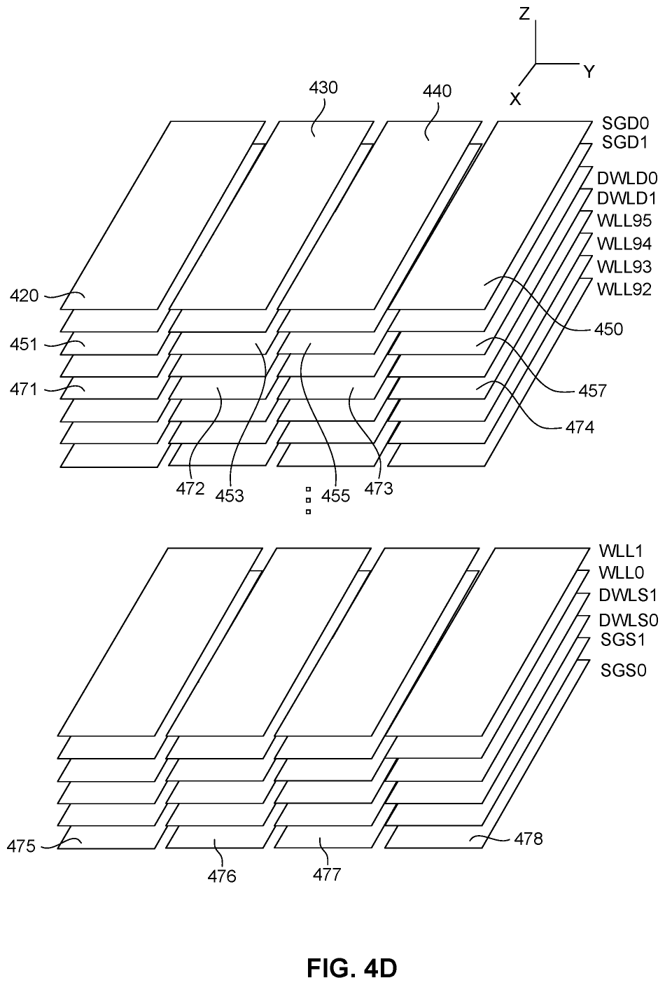

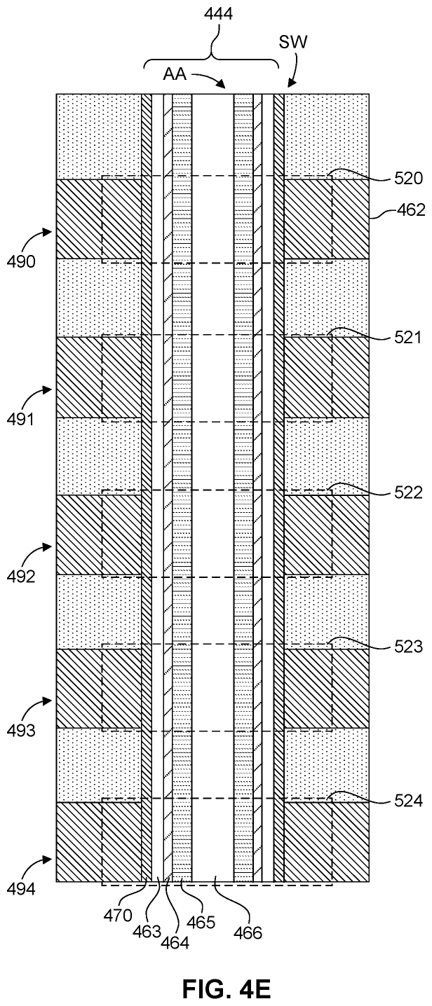

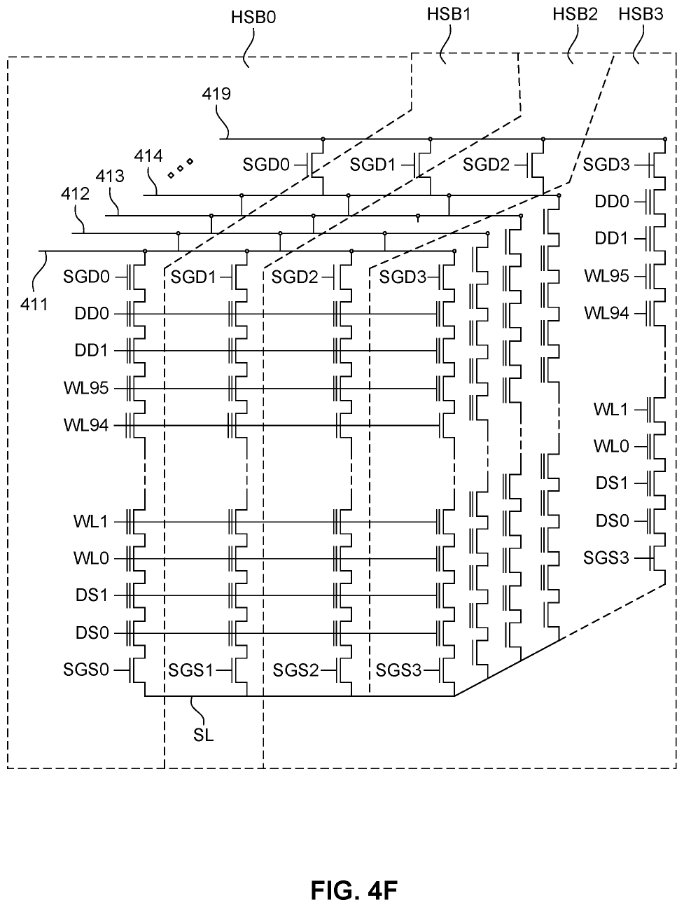

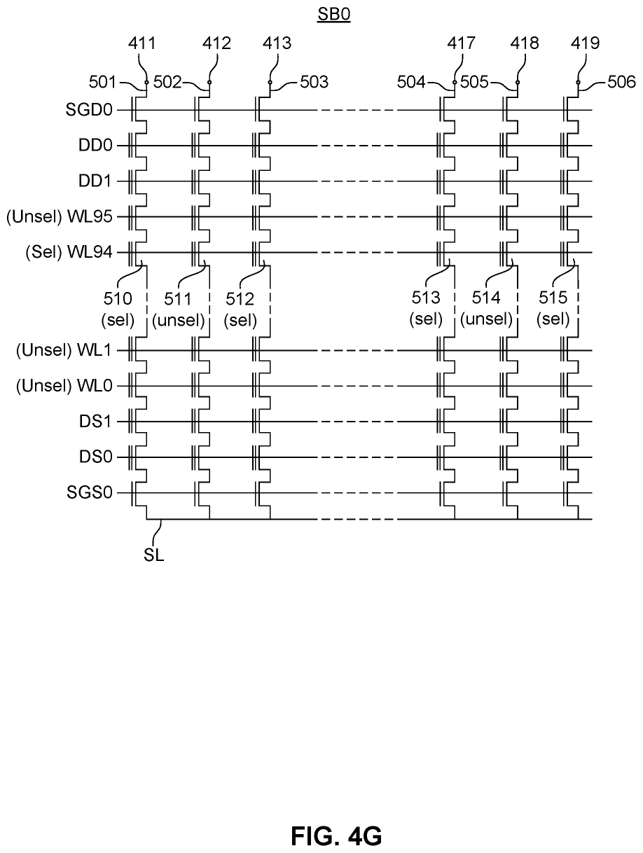

FIG. 3 is a perspective view of a portion of a monolithic 3D memory array that includes a plurality of non-volatile memory cells, and that can comprise memory structure 126 in one embodiment. FIG. 3 illustrates, for example, a portion of one block of memory. The structure depicted includes a set of bitlines (BLs) positioned above a stack of alternating dielectric layers and conductive layers. For example purposes, one of the dielectric layers is marked as D and one of the conductive layers (i.e., wordline layers) is marked as WL. The number of alternating dielectric and conductive layers can vary based on specific implementation requirements. In some embodiments, the 3D memory array includes between 108-300 alternating dielectric and conductive layers. One example embodiment includes 96 data wordline layers, 8 select layers, 6 dummy wordline layers, and 110 dielectric layers. More or less than 108-300 layers can also be used. Data wordline layers include data memory cells. Dummy wordline layers include dummy memory cells. As will be explained below, the alternating dielectric and conductive layers are divided into four “fingers” by local interconnects LI. FIG. 3 shows two fingers and two local interconnects LI. Below the alternating D layers and WL layers is a source line layer SL. Memory holes are formed in the stack of alternating dielectric layers and conductive layers. For example, one of the memory holes is marked as MH. Note that in FIG. 3, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data. More details of the three dimensional monolithic memory array that comprises memory structure 126 is provided below with respect to FIG. 4A-4G.

One of the local interconnects LI separates the block into two horizontal sub-blocks HSB0, HSB1. The block comprises multiple vertical sub-blocks VSB0, VSB1, VSB2. The vertical sub-blocks VSB0, VSB1, VSB2 can also be referred to as “tiers.” Each vertical sub-block extends across the block, in one embodiment. Each horizontal sub-block HSB0, HSB1 in the block is a part of vertical sub-block VSB0. Likewise, each horizontal sub-block HSB0, HSB1 in the block is a part of vertical sub-block VSB1. Likewise, each horizontal sub-block HSB0, HSB1 in the block is a part of vertical sub-block VSB2. For purpose of discussion, vertical sub-block VSB0 will be referred to as a lower vertical sub-block, vertical sub-block VSB1 will be referred to as a middle vertical sub-block, and VSB2 will be referred to as an upper vertical sub-block. In one embodiment, there are two vertical sub-blocks in a block. There could be four or more vertical sub-blocks in a block.

A memory operation for a vertical sub-block may be performed on memory cells in one or more horizontal sub-blocks. For example, a programming operation of memory cells in vertical sub-block VSB0 may include: programming memory cells in horizontal sub-block HSB0 but not horizontal sub-block HSB1; programming memory cells in horizontal sub-block HSB1 but not horizontal sub-block HSB0; or programming memory cells in both horizontal sub-block HSB0 and horizontal sub-block HSB1.

The different vertical sub-blocks VSB0, VSB1, VSB2 are treated as separate units for erase/program purposes, in one embodiment. For example, the memory cells in one vertical sub-block can be erased while leaving valid data in the other vertical sub-blocks. Then, memory cells in the erased vertical sub-block can be programmed while valid data remains in the other vertical sub-blocks. In some cases, memory cells in the middle vertical sub-block VSB1 are programmed while there is valid data in the lower vertical sub-block VSB0 and/or the upper vertical sub-block VSB2. Programming the memory cells in middle vertical sub-block VSB1 presents challenges due to the valid data in the other vertical sub-blocks VSB0, VSB2.

FIG. 4A is a block diagram explaining one example organization of memory structure 126, which is divided into two planes 302 and 304. Each plane is then divided into M blocks. In one example, each plane has about 2000 blocks. However, different numbers of blocks and planes can also be used. In on embodiment, a block of memory cells is a unit of erase. That is, all memory cells of a block are erased together. In other embodiments, memory cells can be grouped into blocks for other reasons, such as to organize the memory structure 126 to enable the signaling and selection circuits. In some embodiments, a block represents a groups of connected memory cells as the memory cells of a block share a common set of wordlines.

FIGS. 4B-4F depict an example three dimensional (“3D”) NAND structure that corresponds to the structure of FIG. 3 and can be used to implement memory structure 126 of FIG. 2. FIG. 4B is a block diagram depicting a top view of a portion of one block from memory structure 126. The portion of the block depicted in FIG. 4B corresponds to portion 306 in block 2 of FIG. 4A. As can be seen from FIG. 4B, the block depicted in FIG. 4B extends in the direction of 332. In one embodiment, the memory array has many layers; however, FIG. 4B only shows the top layer.

FIG. 4B depicts a plurality of circles that represent the vertical columns. Each of the vertical columns include multiple select transistors (also referred to as a select gate or selection gate) and multiple memory cells. In one embodiment, each vertical column implements a NAND string. For example, FIG. 4B depicts vertical columns 422, 432, 442 and 452. Vertical column 422 implements NAND string 482. Vertical column 432 implements NAND string 484. Vertical column 442 implements NAND string 486. Vertical column 452 implements NAND string 488. More details of the vertical columns are provided below. Since the block depicted in FIG. 4B extends in the direction of arrow 332, the block includes more vertical columns than depicted in FIG. 4B.

FIG. 4B also depicts a set of bitlines 415, including bitlines 411, 412, 413, 414, . . . 419. FIG. 4B shows twenty-four bitlines because only a portion of the block is depicted. It is contemplated that more than twenty-four bitlines connected to vertical columns of the block. Each of the circles representing vertical columns has an “x” to indicate its connection to one bitline. For example, bitline 414 is connected to vertical columns 422, 432, 442 and 452.

The block depicted in FIG. 4B includes a set of local interconnects 402, 404, 406, 408 and 410 that connect the various layers to a source line below the vertical columns. Local interconnects 402, 404, 406, 408 and 410 also serve to divide each layer of the block into four regions; for example, the top layer depicted in FIG. 4B is divided into regions 420, 430, 440 and 450, which are referred to as fingers. In the layers of the block that implement memory cells, the four regions are referred to as wordline fingers that are separated by the local interconnects. In one embodiment, the wordline fingers on a common level of a block connect together to form a single wordline. In another embodiment, the wordline fingers on the same level are not connected together. In one example implementation, a bitline only connects to one vertical column in each of regions 420, 430, 440 and 450. In that implementation, each block has sixteen rows of active columns and each bitline connects to four rows in each block. In one embodiment, all of four rows connected to a common bitline are connected to the same wordline (via different wordline fingers on the same level that are connected together); therefore, the system uses the source side selection lines and the drain side selection lines to choose one (or another subset) of the four to be subjected to a memory operation (program, verify, read, and/or erase).

Although FIG. 4B shows each region having four rows of vertical columns, four regions and sixteen rows of vertical columns in a block, those exact numbers are an example implementation. Other embodiments may include more or less regions per block, more or less rows of vertical columns per region and more or less rows of vertical columns per block. FIG. 4B also shows the vertical columns being staggered. In other embodiments, different patterns of staggering can be used. In some embodiments, the vertical columns are not staggered.

FIG. 4C depicts an embodiment of a stack 435 showing a cross-sectional view along line AA of FIG. 4B. Two SGD layers (SGD0, SDG1), two SGS layers (SGS0, SGS1) and six dummy wordline layers DWLD0, DWLD1, DWLM1, DWLM0, DWLS0 and DWLS1 are provided, in addition to the data wordline layers WLL0-WLL95. Each NAND string has a drain side select transistor at the SGD0 layer and a drain side select transistor at the SGD1 layer. In operation, the same voltage may be applied to each layer (SGD0, SGD1), such that the control terminal of each transistor receives the same voltage. Each NAND string has a source side select transistor at the SGS0 layer and a drain side select transistor at the SGS1 layer. In operation, the same voltage may be applied to each layer (SGS0, SGS1), such that the control terminal of each transistor receives the same voltage. Also depicted are dielectric layers DL0-DL106.

Columns 432, 434 of memory cells are depicted in the multi-layer stack. The stack includes a substrate 301, an insulating film 250 on the substrate, and a portion of a source line SL. A portion of the bitline 414 is also depicted. Note that NAND string 484 is connected to the bitline 414. NAND string 484 has a source-end 439 at a bottom of the stack and a drain-end 438 at a top of the stack. The source-end 439 is connected to the source line SL. A conductive via 441 connects the drain-end 438 of NAND string 484 to the bitline 414. The metal-filled slits 404 and 406 from FIG. 4B are also depicted.

The stack 435 is divided into three vertical sub-blocks (VSB0, VSB1, VSB2). Vertical sub-block VSB0 includes WLL0-WLL31. The following layers could also be considered to be a part of vertical sub-block VSB0 (SGS0, SGS1, DWLS0, DWLS1). Vertical sub-block VSB1 includes WLL32-WLL63. Vertical sub-block VSB2 includes WLL64-WLL95. The following layers could also be considered to be a part of vertical sub-block VSB2 (SGD0, SGD1, DWLD0, DWLD1). Each NAND string has a set of data memory cells in each of the vertical sub-blocks. Dummy wordline layer DMLM0 is between vertical sub-block VSB0 and vertical sub-block VSB1. Dummy wordline layer DMLM1 is between vertical sub-block VSB1 and vertical sub-block VSB2. The dummy wordline layers have dummy memory cell transistors that may be used to electrically isolate a first set of memory cell transistors within the memory string (e.g., corresponding with vertical sub-block VSB0 wordlines WLL0-WLL31) from a second set of memory cell transistors within the memory string (e.g., corresponding with the vertical sub-block VSB1 wordlines WLL32-WLL63) during a memory operation (e.g., an erase operation or a programming operation).

In another embodiment, one or more middle junction transistor layers are used to divide the stack 435 into vertical sub-blocks. A middle junction transistor layer contains junction transistors, which do not necessarily contain a charge storage region. Hence, a junction transistor is typically not considered to be a dummy memory cell. Both a junction transistor and a dummy memory cell may be referred to herein as a “non-data transistor.” A non-data transistor, as the term is used herein, is a transistor on a NAND string, wherein the transistor is either configured to not store user or system data or operated in such a way that the transistor is not used to store user data or system data. A wordline that is connected to non-data transistors is referred to herein as a non-data wordline. Examples of non-data wordlines include, but are not limited to, dummy wordlines, and a select line in a middle junction transistor layer.

The stack 435 may have more than three vertical sub-blocks. For example, the stack 435 may be divided into four, five or more vertical sub-blocks. Each of the vertical sub-block contains at least one data memory cell. There may additional layers similar to the middle dummy wordline layers DWLM in order to divide the stack 435 into the additional vertical sub-blocks. In one embodiment, the stack has two vertical sub-blocks.

FIG. 4D depicts an alternative view of the SG layers and wordline layers of the stack 435 of FIG. 4C. The SGD layers SGD0 and SGD0 (the drain-side SG layers) each includes parallel rows of SG lines associated with the drain-side of a set of NAND strings. For example, SGD0 includes drain-side SG regions 420, 430, 440 and 450, consistent with FIG. 4B.

Below the SGD layers are the drain-side dummy wordline layers. Each dummy wordline layer represents a wordline, in one approach, and is connected to a set of dummy memory cells at a given height in the stack. For example, DWLD0 comprises wordline layer regions 451, 453, 455 and 457. A dummy memory cell, also referred to as a non-data memory cell, does not store data and is ineligible to store data, while a data memory cell is eligible to store data. Moreover, the Vth of a dummy memory cell is generally fixed at the time of manufacturer or may be periodically adjusted, while the Vth of the data memory cells changes more frequently, e.g., during erase and programming operations of the data memory cells.

Below the dummy wordline layers are the data wordline layers. For example, WLL95 comprises wordline layer regions 471, 472, 473 and 474. Below the data wordline layers are the source-side dummy wordline layers. Below the source-side dummy wordline layers are the SGS layers. The SGS layers SGS0 and SGS1 (the source-side SG layers) each includes parallel rows of SG lines associated with the source-side of a set of NAND strings. For example, SGS0 includes source-side SG lines 475, 476, 477 and 478. Each SG line can be independently controlled, in one approach. Or, the SG lines can be connected and commonly controlled.

FIG. 4E depicts a view of the region 445 of FIG. 4C. Data memory cell transistors 520 and 521 are above dummy memory cell transistor 522. Below dummy memory cell transistor 522 are data memory cell transistors 523 and 524. A number of layers can be deposited along the sidewall (SW) of the memory hole 444 and/or within each wordline layer, e.g., using atomic layer deposition. For example, each column (e.g., the pillar which is formed by the materials within a memory hole) can include a blocking oxide/block high-k material 470, charge-trapping layer or film 463 such as SiN or other nitride, a tunneling layer 464, a polysilicon body or channel 465, and a dielectric core 466. A wordline layer can include a conductive metal 462 such as Tungsten as a control gate. For example, control gates 490, 491, 492, 493 and 494 are provided. In this example, all of the layers except the metal are provided in the memory hole. In other approaches, some of the layers can be in the control gate layer. Additional pillars are similarly formed in the different memory holes. A pillar can form a columnar active area (AA) of a NAND string.

When a data memory cell transistor is programmed, electrons are stored in a portion of the charge-trapping layer which is associated with the data memory cell transistor. These electrons are drawn into the charge-trapping layer from the channel, and through the tunneling layer. The Vth of a data memory cell transistor is increased in proportion to the amount of stored charge. During an erase operation, the electrons return to the channel. For example, in one embodiment, the erase operation includes removing electrons from the floating gate in order to change the state of the cell to 1. During the erase operation, a large negative voltage is required to repel electrons from the floating gate. This can be accomplished by grounding the control gate and applying a high voltage (e.g., about 18V or more) to the substate. As a result, electrons are removed from the floating gate due to the FN tunneling effect.

Non-data transistors (e.g., select transistors, dummy memory cell transistors) may also include the charge trapping layer 463. In FIG. 4E, dummy memory cell transistor 522 includes the charge trapping layer 463. Thus, the threshold voltage of at least some non-data transistors may also be adjusted by storing or removing electrons from the charge trapping layer 463. It is not required that all non-data transistors have an adjustable Vth. For example, the charge trapping layer 463 is not required to be present in every select transistor.

Each of the memory holes can be filled with a plurality of annular layers comprising a blocking oxide layer, a charge trapping layer, a tunneling layer and a channel layer. A core region of each of the memory holes is filled with a body material, and the plurality of annular layers are between the core region and the WLLs in each of the memory holes. In some cases, the tunneling layer 464 can comprise multiple layers such as in an oxide-nitride-oxide configuration.

FIG. 4F is a schematic diagram of a portion of the memory depicted in FIGS. 3-4E. FIG. 4F shows physical wordlines WLL0-WLL95 running across the entire block. The structure of FIG. 4F corresponds to portion 306 in Block 2 of FIGS. 4A-E, including bitlines 411, 412, 413, 414, . . . 419. Within the block, each bitline is connected to four NAND strings. Drain side selection lines SGD0, SGD1, SGD2 and SGD3 are used to determine which of the four NAND strings connect to the associated bitline(s). Source side selection lines SGS0, SGS1, SGS2 and SGS3 are used to determine which of the four NAND strings connect to the common source line. The block can also be thought of as divided into four horizontal sub-blocks HSB0, HSB1, HSB2 and HSB3. Horizontal sub-block HSB0 corresponds to those vertical NAND strings controlled by SGD0 and SGS0, Horizontal sub-block HSB1 corresponds to those vertical NAND strings controlled by SGD1 and SGS1, Horizontal sub-block HSB2 corresponds to those vertical NAND strings controlled by SGD2 and SGS2, and Horizontal sub-block HSB3 corresponds to those vertical NAND strings controlled by SGD3 and SGS3.

FIG. 4G is a schematic of horizontal sub-block HSB0. Horizontal sub-blocks HSB1, HSB2 and HSB3 have similar structures. FIG. 4G shows physical wordlines WL0-WL95 running across the entire sub-block S0. All of the NAND strings of sub-block S0 are connected to SGD0 and SGS0. FIG. 4G only depicts six NAND stings 501, 502, 503, 504, 505 and 506; however, horizontal sub-block HSB0 will have thousands of NAND strings (e.g., 15,000 or more).

FIG. 4G is being used to explain the concept of a selected memory cell. A memory operation is an operation designed to use the memory for its purpose and includes one or more of reading data, writing/programming data, erasing memory cells, refreshing data in memory cells, and the like. During any given memory operation, a subset of the memory cells will be identified to be subjected to one or more parts of the memory operation. These memory cells identified to be subjected to the memory operation are referred to as selected memory cells. Memory cells that have not been identified to be subjected to the memory operation are referred to as unselected memory cells. Depending on the memory architecture, the memory type, and the memory operation, unselected memory cells may be actively or passively excluded from being subjected to the memory operation.

As an example of selected memory cells and unselected memory cells, during a programming process, the set of memory cells intended to take on a new electrical characteristic (or other characteristic) to reflect a changed programming state are referred to as the selected memory cells while the memory cells that are not intended to take on a new electrical characteristic (or other characteristic) to reflect a changed programming state are referred to as the unselected memory cells. In certain situations, unselected memory cells may be connected to the same wordline as selected memory cells. Unselected memory cells may also be connected to different wordlines than selected memory cells. Similarly, during a reading process, the set of memory cells to be read are referred to as the selected memory cells while the memory cells that are not intended to be read are referred to as the unselected memory cells.

To better understand the concept of selected memory cells and unselected memory cells, assume a programming operation is to be performed and, for example purposes only, that wordline WL94 and horizontal sub-block HS0 are selected for programming (see FIG. 4G). That means that all of the memory cells connected to WL94 that are in horizontal sub-blocks HSB1, HSB2 and HSB3 (the other horizontal sub-blocks) are unselected memory cells. Some of the memory cells connected to WL94 in horizontal sub-block HS0 are selected memory cells and some of the memory cells connected to WL94 in horizontal sub-block HS0 are unselected memory cells depending on how the programming operation is performed and the data pattern being programmed. For example, those memory cells that are to remain in the erased state S0 will be unselected memory cells, because their programming state will not change in order to store the desired data pattern, while those memory cells that are intended to take on a new electrical characteristic (or other characteristic) to reflect a changed programming state (e.g., programmed to states S1-S7) are selected memory cells. Looking at FIG. 4G, assume for example purposes, that memory cells 511 and 514 (which are connected to wordline WL94) are to remain in the erased state; therefore, memory cells 511 and 514 are unselected memory cells (labeled unset in FIG. 4G). Additionally, assume for example purposes that memory cells 510, 512, 513 and 515 (which are connected to wordline WL94) are to be programmed to any of the data states S1-S7; therefore, memory cells 510, 512, 513 and 515 are selected memory cells (labeled sel in FIG. 4G).

Although the example memory system of FIGS. 3-4G is a three dimensional memory structure that includes vertical NAND strings with charge-trapping material, other (2D and 3D) memory structures can also be used with the technology described herein.

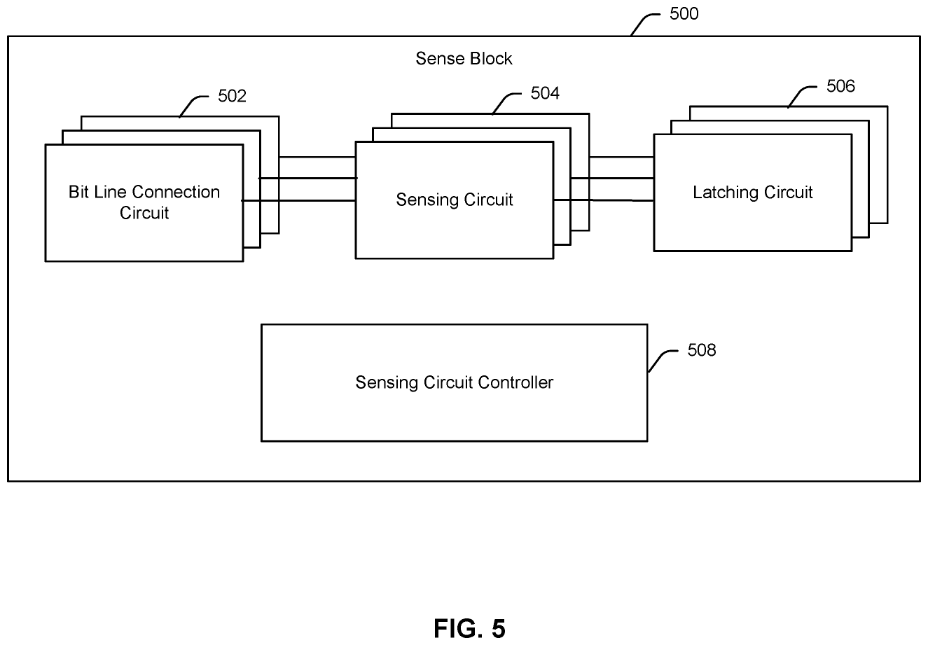

FIG. 5 is a block diagram of an example configuration of a sense block 500, which may be representative of one of the sense blocks 150. The sense block 500 may include a plurality of sense circuits 504 and a plurality of sets of latching circuits 506. For example, there can be 16k sets of sense circuits 504 and latching circuits 506. In other examples, there can be a set of sense circuits 504 and a respective latching circuit 506 for each memory cell in a memory array, for example. In some embodiments, each sense circuit 504 (which may also include sense amplifier circuitry) may be associated with a respective one of the latching circuits 506. That is, each sense circuit 504 may be configured to communicate with and/or perform a sense operation using data and/or storing data into its associated latching circuit 506.

Additionally, the sense block 500 may include a sense circuit controller 508 that is configured to control operation of the sense circuits 504 (and/or the sets of latches 506) of the sense block 500. As described in further detail below, the sense circuit controller 508 may control operation of the sense circuits 504 and the latches 506 by outputting control signals to terminals of the sense circuits 504 and the latches 506.

The sense circuit controller 508 may be implemented in hardware, firmware, software, or combinations thereof. For example, the sense circuit controller 508 may include a processor that executes computer instructions stored in a memory to perform at least some of its functions. Controller 508 can be configured with various modules to perform one or more functions. Each module may include one or more instructions for execution of logic of one or more circuits described herein. For example, instructions may include instructions for generating one or more signals or sensing one or more voltage levels. Instructions may further include instructions for executing any of steps of any of the methods disclosed herein. The controller 508 may send messages and receive data, including program code, through one or more communication interface(s). The received code may be executed by a processor of the controller 508 as it is received, and/or stored in storage device, or other non-volatile storage for later execution.

Sense circuits 504 described herein can be coupled to bitlines and/or wordlines. Bitline connection circuit 502 is depicted in FIG. 5 as part of sense block 500. It should be appreciated, however, that the bitline connection circuit 502 may be, more generally, part of read/write circuit 128. Bitline connection circuit 502 may be configured to electrically connect and disconnect the ith bitline BL(i) from the sensing circuit 504 (and the latching circuit 506). In the case of a 3D NAND architecture, the ith bitline BL(i) may be connected to a respective memory hole from each NAND string of each NAND block of the 3D structure. In the case of a 2D NAND architecture, the ith bitline BL(i) may be connected to an associated NAND string. The ith bitline BL(i) may be one of a plurality bitlines and the NAND string may be one of a plurality of NAND strings included in a memory cell structure of a memory die. The NAND string can include one or more memory cells. For a read operation, a target memory cell can be a memory cell from which data is to be read and thus, for which a sense operation is performed. For a verification operation, a target memory cell can be a memory cell being programmed in an associated program-verify operation.

When the bitline connection circuitry connects the ith bitline BL(i) to the sensing circuit 504 (e.g. for a sense operation), current may flow from the sense circuit 504 to the ith bitline BL(i). Alternatively, when the bitline connection circuitry disconnects the ith bitline BL(i) from the sense circuit 504, current may be prevented from flowing from the sensing circuit 504 to the ith bitline BL(i). Bitline connection circuit 502 may include a bitline biasing circuit configured to bias the ith bitline BL(i) by generating a bitline bias voltage at a bitline bias node. The amount of the bitline bias voltage may depend on whether the ith bitline BL(i) is a selected bitline or an unselected bitline (see above for distinction). In particular, when the ith bitline BL(i) is a selected bitline, the bitline biasing may allow the bitline bias voltage at the high supply voltage level or a level corresponding to the high supply voltage, and when the ith bitline BL(i) is an unselected bitline, the bitline biasing circuit may generate the bitline bias voltage at the cell source voltage level or a level corresponding to the cell source voltage.

Sensing circuits 504 described herein can include a pre-charge circuit path configured to pre-charge one or more sense node(s) with a voltage at a pre-charge level during a sense operation. A latching circuit 506, in response to receiving a control signal at a high voltage level at a first transistor of the latch circuit 506, can enable a pre-charge circuit path to pre-charge the sense node with the voltage at the pre-charge level.

In one embodiment, during a pre-charge phase of a programming operation of selected memory cells in a vertical sub-block VSB1 (as seen in FIG. 3), an overdrive voltage is applied to programmed memory cells in vertical sub-block VSB2, while applying a bypass voltage to one or more unprogrammed memory cells of vertical sub-block VBS1, and while applying a pre-charge voltage to but line (BL) connected to an unselected NAND string to adequately charge. During a programming phase, boosting voltages may be applied to wordlines to boost the channel voltage of the unselected NAND string to thereby prevent program disturb of an unselected memory cell on the unselected NAND string when a program voltage is applied to a selected wordline. The foregoing allows memory cells in the middle vertical sub-block VSB1 to be programmed while valid data exists in the upper vertical sub-block VSB0 and the upper vertical sub-block VSB2.

In one embodiment, during a pre-charge phase of a programming operation of a selected memory ell in vertical subs-block VSB1, and overdrive voltage is applied to programmed memory cells in vertical sub-block VSB0, while applying a bypass voltage to one or more unprogrammed memory cells of vertical sub-block VSB1, and while applying a pre-charge voltage to a source line (SL) connected to an unselected NAND string. The foregoing allows the channel of the unselected NAND string to adequately charge. During a programming phase, boosting voltages may be applied to wordline to boost the channel voltage of the unselected NAND string to thereby prevent program disturb of an unselected memory cell on the unselected NAND string when a program voltage is applied to a selected wordline. The foregoing allows memory cells in the middle vertical sub-block VSB1 to be programmed while valid data exists in the lower vertical sub-block VSB0. The foregoing allows memory cells in the middle vertical sub-block VSB1 to be programmed even if valid data exists in both the lower vertical sub-block VSB0 and the upper vertical sub-bloc VSB2.

In one embodiment, the channel of the unselected NAND string is pre-charged from both the bit line and the source line. The foregoing allows the channel of the unselected NAND string to adequately charge. The foregoing allows memory cells in the middle vertical sub-block VSB1 to be programmed even if valid data exists in both the lower vertical sub-block VSB0 and the upper vertical sub-block VSB2.

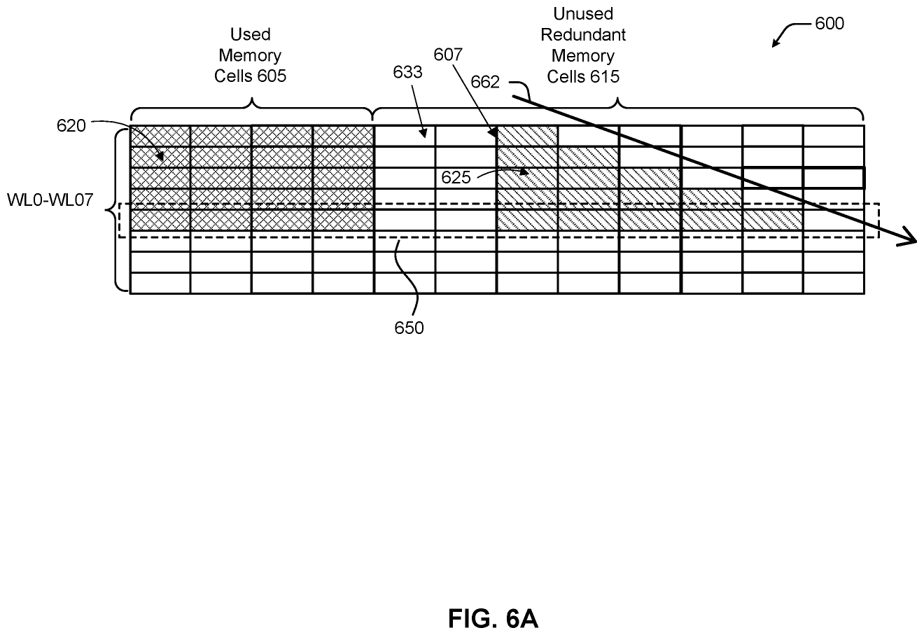

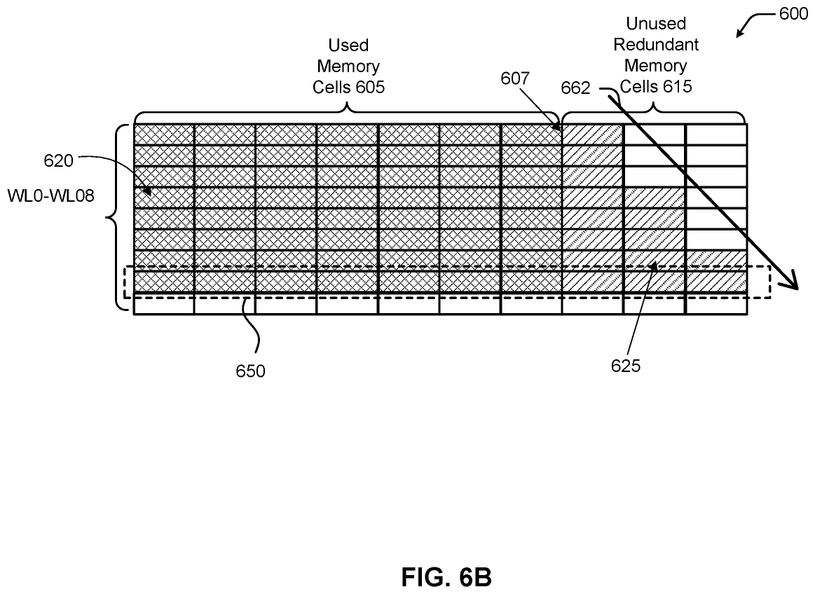

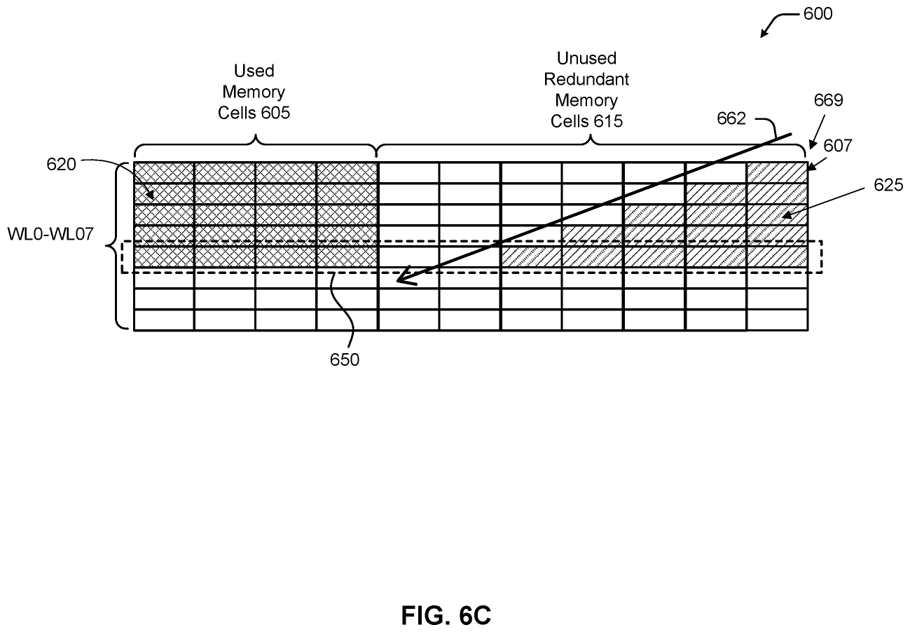

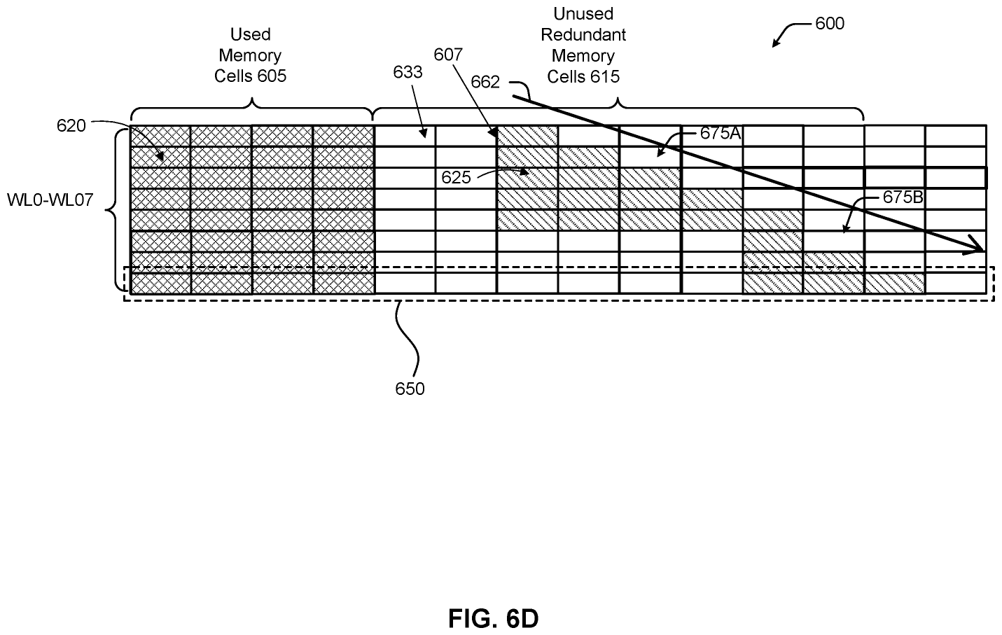

FIG. 6A is an illustration of an example of a plurality of specially programmed cells, according to one embodiment. Here, the plurality of memory cells 600 include wordlines WL0-WL07 and columns of used and unused redundant memory cells 605, 615 respectively. The used memory cells 605 include a plurality of programmed memory cells 620. The unused redundant cells 615 include a plurality of specially programmed memory cells 625.

The specially programmed memory cells 625 are unused redundant memory cells 615 programmed with one or more markers. The one or more markers can include a plurality of binary values that depend on the type of flash memory in which they are stored. For example, SLC NAND flash uses a single bit of data per cell, which can be two binary values 0 or 1. MLC NAND flash uses two bits of data per cell, with 4 binary values. 3D TLC NAND flash uses three bits of data per cell, with 8 binary values. QLC NAND uses four bits of data per cell, with 16 possible values. Furthermore, in some embodiments, the memory cells can be programmed in an abbreviated pyramidal structure (i.e., specially programming a subset of bytes).

As seen in FIG. 6A, WL0 includes one specially programmed memory cell 625. WL1 includes two specially programmed memory cells 625. WL2 includes three specially programmed memory cells 625. WL3 includes four specially programmed memory cells 625. WL4 includes five specially programmed memory cells. With each increasing wordline (e.g., WL+1) an additional specially programmed memory cell is programmed. As seen in FIGS. 6A-6C, in one embodiment, the programming of unused redundant memory cells to create a set of specially programmed memory cells, creates an expanding pyramidal structure of specially programmed cells.

The specially programmed memory cells 625 are programmed along with the regular programming of memory cells 620. For example, when a first memory cell in a first wordline is programmed with data, the sense block 500 specially programs an unused redundant memory cell in the first wordline with a first specially programmed cell to track the programmed wordline. As a second wordline is programmed, the sense block 500 programs an unused redundant memory cell 615 in the second wordline with a specially programed memory cell 625 to track the second programmed wordline. As previously mentioned, in this embodiment, the sense block 500 adds an additional specially programmed memory cell 625 with each additional wordline so that an erase verify or string sense operation can be used to determine the location of where the programming of the used memory cells 605 stopped.

Specifically, in one embodiment, programming a set of memory cells to create specially programmed memory cells includes adjusting the bitline and gate voltages applied to a transistor to alter the threshold voltage of the memory cell. For example, in one configuration, specially programmed cells are programmed such that the threshold voltage of the gate is higher than the voltage applied to the gate during a string sense operation or erase verify operation. By altering the threshold voltage of the memory cell, the voltage applied to the gate may not exceed the threshold voltage, therefore preventing transistor from conducting in saturation mode. The string sense and erase verify operations can then be used to apply a voltage to each gate to determine the non-conducting string(s) associated with the specially programmed memory cell(s). As each new wordline is programmed, an additional specially programmed memory cell is programmed in the unused redundant memory cells. Thus, the sense block can track the progress of the programming operation by tracking/counting the number of non-conducting strings. In one embodiment, the sense block can track the progress of the programming operation by tracking/counting the number of 0's. In another embodiment, the sense block can track the progress of the programming operation by tracking/counting the number of 1's.

For example, if programming stopped at WL2, the sense block 500 can count the total number of programmed cells programmed, to determine that the programming stopped on WL2. This is especially helpful when programming is interrupted, as the system can quickly and accurately reference the most recent WL in which it was programming, thus removing the need to conduct a lengthy binary search throughout the entirety of the open block.

In another embodiment, the sense block can determine the last programmed wordline by identifying the memory cell that signifies the highest programmed location. For example, the sense block could conduct a sensing operation to determine the non-conducting string associated with a memory cell that was specially programmed to represent the last programmed location. Thus, the sense block could determine the last programmed wordline without tracking/counting the number of non-conducting strings.

Furthermore, in some embodiments, it can be foreseeable that one or more specially programmed memory cells are incorrectly programmed such that, during a string sense operation, one or more specially programmed strings conduct. For example, one or more memory cells within one or more strings may be incorrectly programmed such that the threshold voltage of the gate is not altered sufficiently to prevent the string from conducting during a sensing operation. Thus, when a sensing operation is applied to the string, the string will conduct. Given that one or more specially programmed memory cells may be incorrectly programmed, the sense block can be programmed to disregard (e.g., “ignore”) some non-conducting or conducting strings that may be incorrectly programmed. For example, a sense operation returns five non-conducting strings with one conducting string in-between the non-conducting string, then the sense block 500 can disregard the one conducting string as likely improperly specially programmed. In addition, in another example, if the latching circuit stores ten 0 values and two 1 values randomly in-between the ten 0 values, then the sense block can disregard the two 1 values. This also applied in the inverse, where the latching circuit may store ten 1 values and two 0 values in-between the ten 1 values. Thus, clearly invalid values can be disregarded by the sense block.

Furthermore, in one embodiment, the specially programmed memory cells can include specific non-user (e.g., not used in typical programming operations) columns of memory cells. These non-user columns of memory cells are cells that are not used for redundancy (i.e., memory cells that are not unused redundant memory cells). Thus, specific non-user columns of memory cells can be programmed such that when a string sense operation is applied to each string, non-conducting strings (or inversely conducting strings) associated with the specially programmed specific non-user memory cells can be used to determine the last programmed wordline. In addition, in some embodiments, extra user columns that are not used by the system for typical programming operations can be used in place of the unused redundant memory cells. For example, the NAND or system could determine whether left over user columns exists. These left over user columns can also be specially programmed as previous described above.

As seen in FIG. 6A, the plurality of memory cells 600 further include a gap created by two columns of unused redundant memory cells 615 between the programmed memory cells 620 and the specially programmed memory cells 625. The gap 633 is formed by the arbitrary starting point 607 of the specially programmed memory cells 625 and the direction 662 in which the specially programmed memory cells are proportionally increased. As discussed in further detail below, the starting point 607 of the specially programmed memory cells 625 and the direction 662 in which the specially programmed cells are increased can change depending on the embodiment.

Furthermore, it should be noted that the specially programmed memory cells do not need to be isolated. Programmed (i.e., user memory cells) and specially programmed memory cells can participate in erase verify and string sense operations. Therefore, the specially programmed memory cells do not require isolation from programmed memory cells since only the specially programmed memory cells are counted.

FIG. 6B is an illustration of an example of a plurality of specially programmed cells, according to one embodiment. Here, the plurality of memory cells 600 includes wordlines WL0-WL08. The number of specially programmed cells are repeated instead of increased by 1 with every WL. For example, WL0 includes one programmed cell, WL1 includes one programmed cell, WL2 includes one programmed cell, WL3 includes two programmed cells, WL4 includes two programmed cells, WL4 includes two programmed cells, WL5 includes three programmed cells, WL6 includes three programmed cells, WL7 includes three programmed cells. Typical memory structures have a limited number of redundant unused memory cells 615. Thus, repeating the number of specially programmed cells 625 in one or more wordlines is useful in configurations where there are too few unused redundant memory cells 615 to have walking rows of specially programmed memory cells 615 as shown in FIG. 6A.

The specially programmed memory cells 625 are programmed along with the regular programming of memory cells 620 to allow the sense block 500 to follow each programmed wordline in the used memory cells 605. For example, when a first memory cell in a first wordline is programmed with data, the sense block 500 specially programs an unused redundant memory cell in the first wordline with a first specially programmed cell to track the programmed wordline. As a second wordline is programmed, the sense block 500 programs an unused redundant memory cell 615 in the second wordline with a specially programed memory cell 625 to track the second programmed wordline, signaling the location of where the programming of the used memory cells 605 stopped.

In this embodiment, the sense block 500 determines the wordline in which programming stopped by locating the highest number of specially programmed cells. Here, the sense block 500 locates the last programmed wordline by counting the number of specially programmed memory cells 625 in each wordline and determining that the wordline with the highest count of the specially programmed memory cells 625 is the last programmed wordline. Thus, in this embodiment, the sense block 500 only needs to determine the wordline with the highest count of specially programmed memory cells 625.

In another embodiment, each one of the specially programmed memory cells are programmed in a diagonal structure. Unlike the pyramidal structure, the diagonal structure does not require an ever increasing amount of specially programmed memory cells with each increasing wordline. Instead the diagonal structure of specially programmed memory cells only requires a new specially programmed cell in a neighboring column in a neighboring row. For example, if a first memory cell in a first row and first column was programmed, then a second memory cell in a second row in a second column could be specially programmed to track the last programmed wordline. This process of diagonally programming memory cells could be continued for each additional programmed wordline. Thus, unlike the pyramidal structure (where a first memory cell in a first row and first column is programmed and a first and second memory cell in the second row and first and second column are programmed), a single memory cell can be specially programmed to track the last programmed wordline.

FIG. 6C is an illustration of an example of a plurality of specially programmed cells, according to one embodiment. Typical memory structures include a finite number of memory cells, which include used and unused memory cells. In this embodiment, the rows of walking specially programmed memory cells 625 start at a column of unused redundant memory cells furthest away from the plurality of used memory cells 620. The column of unused redundant memory cells on the outmost portion of the memory block is hereafter referred to as the “last column of unused redundant cell memory 669”. Instead of programming the specially programmed memory cells 625 from a first direction as seen in FIG. 5, the specially programmed memory cells 625 are programmed in a second direction that is the opposite of the first direction. By using a starting point 607 at the last column of unused redundant memory cells 669, the sense block 500 starts from a known starting point 607, unlike the starting point of FIGS. 6A and 6B, which may require the sense block 500 to search to find the starting point. Thus, the sense block 500 does not have to use additional computing power to locate the starting point of the specially programmed memory cells.

FIG. 6D is an illustration of an example of a plurality of specially programmed cells, according to one embodiment. In one embodiment, the expanding pyramidal structure includes a plurality of portions 675A, 675B of specially programmed pyramidal structures. For example, in one embodiment, a first portion 675A of specially programmed memory cells may include WL0 programmed with one specially programmed cell, WL1 programmed with two specially programmed cells, WL2 programmed with three specially programmed cells, WL3 programmed with four specially programmed cells, WL4 programmed with five specially programmed cells. The second portion 675B of specially programmed memory cells includes WL5 programmed with one specially programmed cell, WL6 programmed with two specially programmed cells, and WL7 programmed with three specially programmed cells.

In this embodiment, the sense block can track the last programmed wordline using the erase verify or string sense operations by applying a voltage to each string. As previously mentioned, when a redundant memory cell is specially programmed, the threshold voltage of the cell is altered such that when a erase verify or string sense operation is applied, the string will fail to conduct thus displaying a 0 that can be tracked and counted.

Even though the specially programmed cells are programmed in two pyramidal portions, each programmed wordline still includes at least one specially programmed memory cell. Thus, when a string sense or erase verify operation is applied to each string, the strings that include at least one specially programmed memory cell will fail to conduct, thereby allowing the sense block to track the last programmed wordline by tracking the strings that fail to conduct (e.g., counting the number of 0s, or counting the number of 1s inversely).

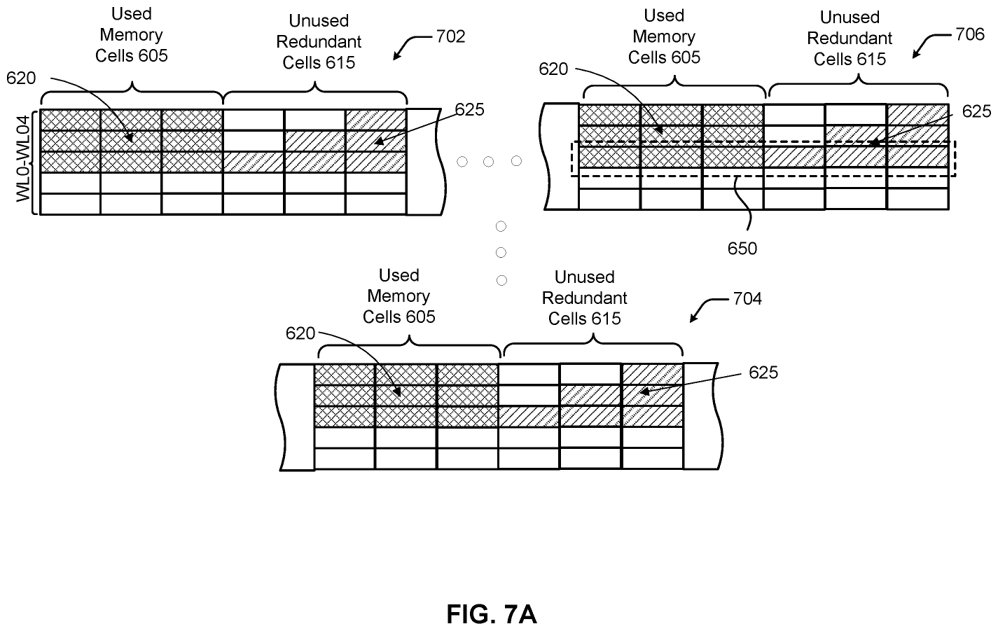

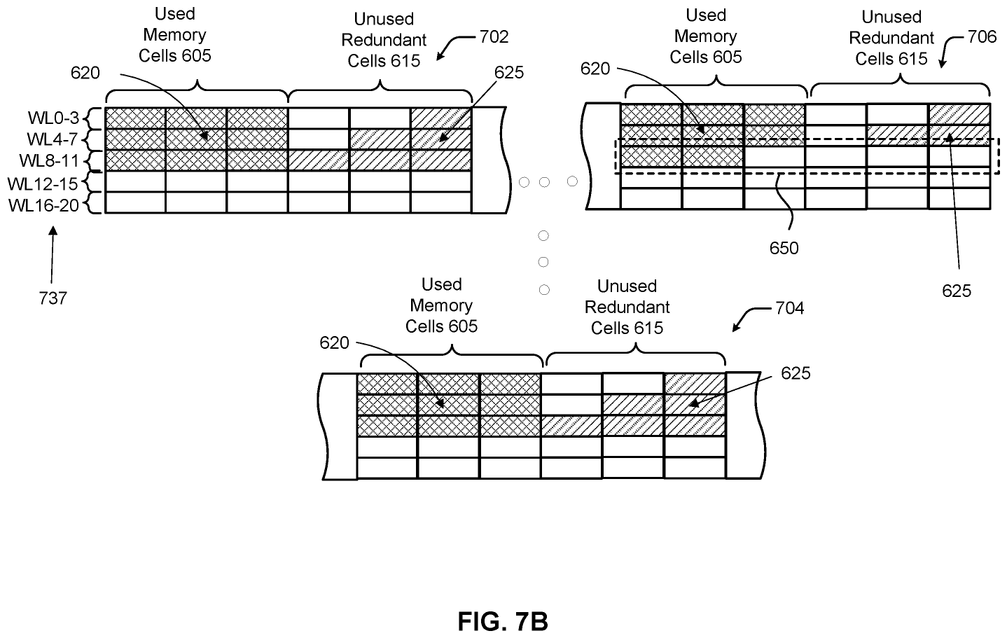

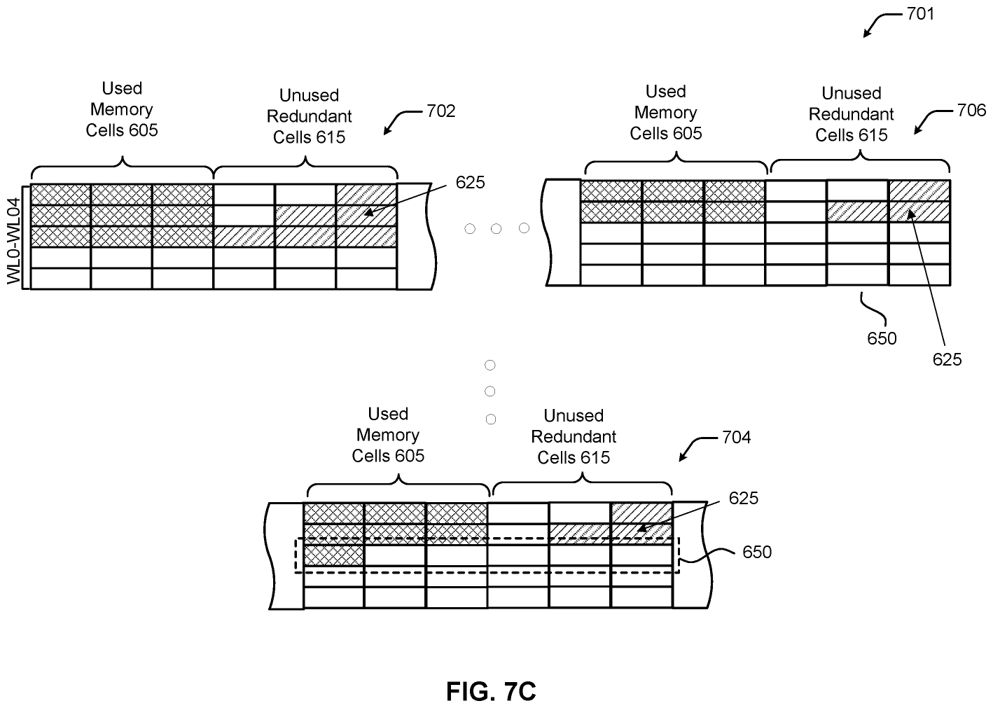

FIG. 7A is an illustration of an example of a plurality of specially programmed memory cells programmed according to an independent plane scheme. The independent plane scheme 701 includes a plurality of planes 702, 704 and 706. Each plane 702, 704 and 706 includes a plurality of memory cells 600 that include wordlines WL0-WL4. Here, the sense block 500 programs each plane 702,704,706 according to the same programming scheme. For example, in plane 702, WL0 includes one specially programmed memory cell 620, WL1 includes two specially programmed memory cells 620, WL2 includes three specially programmed memory cells 620. In plane 704, WL0 includes one specially programmed memory cell 620, WL1 includes two specially programmed memory cells 620, WL2 includes three specially programmed memory cells 620. In plane 706, WL0 includes one specially programmed memory cell 620, WL1 includes two specially programmed memory cells 620, WL2 includes three specially programmed memory cells 620.

FIG. 7B is an illustration of an example of a plurality of specially programmed memory cells programmed according to a linked plane scheme. In one embodiment, each plane includes a string. In one embodiment, the plane can include one or more blocks, with each block containing one or more strings. For example, the first plane may contain multiple blocks with each block containing four strings. As previously mention in FIG. 4B, in some embodiments, the memory structure includes one or more wordline fingers on the same level. In this embodiment, the linked plane scheme includes five wordline levels 737. The first level includes WL0-3, the second level includes WL4-7, the third level includes WL8-11, the fourth level includes WL12-15, and the fifth level includes WL16-20.

As seen in FIG. 7B, the first level (WL0-3), and second level (WL4-7) include the same specially programmed memory cells 625 in each plane 702, 704 and 706. However, the number of specially programmed memory cells 625 third level (WL8-11) in each plane 702, 704 and 706 is not the same. As seen further in FIG. 7B, WL8-11 in the first plane 702 and second plane 704 includes 3 specially programmed memory cells. However, WL8-11 in the third plane 706 includes 0 specially programmed memory cells.

Here, the sense block 500 tracks the last programmed wordline across one or more strings. Thus allowing the sense block 500 to determine the string in which the wordline was last programmed. To determine the last programmed wordline the sense block 500 first string senses one or more strings within the memory structure to isolate the specially programmed memory cells 625. The sense block 500 then counts the number of specially programmed memory cells 625 within each plane. By comparing the number of specially programmed memory cells within each plane, the sense block 500 is able to determine the plane in which the last programmed wordline resides. For example, as seen in FIG. 7B, the sense block 500 counts the number of specially programmed memory cells 625 in the first plane 702, and compares that number to the number of specially programmed memory cells 625 in the next plane 704. Since, in this example, the number of specially programmed memory cells 625 is the same in the first plane 702 and the second plane 704, the sense block 500 advances to comparing the next plane. By advancing to the next plane, the sense block 500 counts the number of specially programmed memory cells 625 in the third plane 706, and compares that number to the number of specially programmed memory cells 625 in the second plane 704. Because the number of specially programmed memory cells 625 in the third plane 706 is less than the number of specially programmed memory cells 625 in the second plane 704, the sense block 500 is able to determine that the last programmed wordline 650 is in the third plane 706. Whereafter, once the sense block 500 has determined the last programmed plane, the sense block 500 can repeat the methods described in FIGS. 6A-6C to locate the last programmed wordline.

FIG. 7C is an illustration of an example of a plurality of specially programmed memory cells. In this example, the sense block 500 scans each plane 702, 704 and 706 to determine which string was the last string programmed. Once the sense block 500 has determined which string was the last string programmed, the sense block 500 determines the last programmed wordline 650 within that string. The sense block 500 starts by performing a first sensing operation on the first plane 702 and determines the number of specially programmed cells within the first plane 702. The sense block 500 then performs a second sensing operation on the second plane 704 and determines the number of specially programmed cells within the second plane 704. The sense block 500 then compares the number of specially programmed cells in each plane 702 and 704. If the number of specially programmed cells in plane 702 is greater than or equal to the number of specially programmed cells in plane 704, the sense block 500 moves on to the next plane 706 are repeats the same steps replacing the sensing and counting operation of the first plane 702 with that of the second plane 704, and the sensing and counting operation of the second plane 704 with the third plane 706. However, as seen in FIG. 7C, the number of specially programmed cells 620 in the second plane 704 is less than the number of specially programmed memory cells 620 in the first plane 702. Thus, the sense block 500 would determine that the last programmed wordline 650 is in the second plane 704. Furthermore, once the sense block 500 determines that the last programmed wordline 650 is in the second plane 704, the sense block 500 counts the number of specially programmed memory cells 620 to determine the last programmed wordline 650. The wordline with the greatest number of specially programmed memory cells 620 is the last programmed wordline 650. Here, the last programmed wordline is WL2.

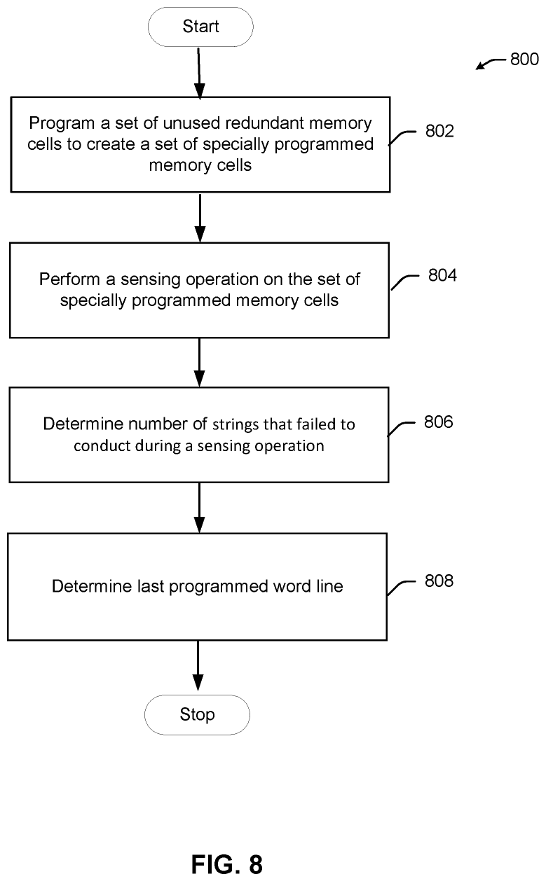

FIG. 8 depicts a method 800 of using the wordline tracking system, according to one embodiment. Here, the method 800 includes programming a set of unused redundant memory cells to create specially programmed memory cells, performing a sensing operation on the set of specially programmed memory cells, determining the number of strings that failed to conduct during a sensing operation, and determining the last programmed wordline.

At activity 802, the method 800 includes programming a set of unused redundant memory cells to create specially programmed memory cells. As previously mentioned, each memory cell in the array of memory cells can be programmed to create a specially programmed memory cell. In one embodiment, a set of unused redundant memory cells are programmed to create specially programmed memory cells by altering the bitline voltage and the gate voltage applied to the cell. When a string sensing operation is conducted, the specially programmed cell will cause the string to fail to conduct, and return a value of 0 at the sensing circuit. Thus, by tracking/counting the strings that failed to conduct, the sense block 500 can determine the last programmed wordline.

At activity 804, the method 800 includes performing a sensing operation on a set of specially programmed memory cells. In one embodiment, performing the sensing operation includes performing a erase verify operation or string sense operation to sense if an unused cell has been specially programmed. At activity 806, the method 800 includes counting the number of strings that failed to conduct during a sensing operation. At activity 808, the sense block 500 is able to determine the last programmed wordline by counting the number of strings that failed to conduct during a sensing operation. In one embodiment, the sense block 500 counts the total number of strings that failed to conduct during a sensing operation throughout the block to determine the last programmed wordline. Furthermore in one embodiment, the number of specially programmed memory cells 620 can be determined by subtracting the strings that failed to conduct during a sensing operation s from the number of unused redundant memory cells in a set of unused redundant memory cells. For example, if the sense block counts a first number of's (wherein each 0 is representative of strings that failed to conduct during the erase verify or string sense operation), the sense block can subtract the first number of 0s from the number of unused redundant memory cells. In another example, if the sense block counts a first number of 0s, the sense block can subtract the first number of 0s from the number of 1s (wherein each 1 is representative of strings that did not fail to conduct). In yet another example, the sense block can count the total number of “1”s and subtract them from the amount of unused redundant memory cells to determine the last programmed wordline.

Alternatively, in embodiments where counting the number of strings that failed to conduct during a sensing operation does not equal the maximum number of wordlines, the sense block 500 would still assist in narrowing the search for the last programmed wordline 650. For example, if the sense block 500 were to count 32 0s (wherein each 0 is associated with a string that failed to conduct during a string sense operation or an erase verify) instead of 30 0s, because some specially programmed memory cells are corrupted or imperfect, the sense block 500 would still be able to narrow down the general location of the last wordline where programming stopped, so that any binary searching applied later would not have to painstakingly search through the entire block.

The processes and algorithms may be implemented partially or wholly in application-specific circuitry. The various features and processes described above may be used independently of one another, or may be combined in various ways. Different combinations and sub-combinations are intended to fall within the scope of this disclosure, and certain method or process blocks may be omitted in some implementations. The methods and processes described herein are also not limited to any particular sequence, and the blocks or states relating thereto can be performed in other sequences that are appropriate, or may be performed in parallel, or in some other manner. Blocks or states may be added to or removed from the disclosed example embodiments.

As used herein, a circuit might be implemented utilizing any form of hardware, software, or a combination thereof. For example, one or more processors, controllers, ASICs, PLAs, PALs, CPLDs, FPGAs, logical components, software routines or other mechanisms might be implemented to make up a circuit. In implementation, the various circuits described herein might be implemented as discrete circuits or the functions and features described can be shared in part or in total among one or more circuits. Even though various features or elements of functionality may be individually described or claimed as separate circuits, these features and functionality can be shared among one or more common circuits, and such description shall not require or imply that separate circuits are required to implement such features or functionality.

As used herein, the term “or” may be construed in either an inclusive or exclusive sense. Moreover, the description of resources, operations, or structures in the singular shall not be read to exclude the plural. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps.

Terms and phrases used in this document, and variations thereof, unless otherwise expressly stated, should be construed as open ended as opposed to limiting. Adjectives such as “conventional,” “traditional,” “normal,” “standard,” “known,” and terms of similar meaning should not be construed as limiting the item described to a given time period or to an item available as of a given time, but instead should be read to encompass conventional, traditional, normal, or standard technologies that may be available or known now or at any time in the future. The presence of broadening words and phrases such as “one or more,” “at least,” “but not limited to” or other like phrases in some instances shall not be read to mean that the narrower case is intended or required in instances where such broadening phrases may be absent.

It is intended that the foregoing be understood as an illustration of selected forms that the invention can take and not as a definition of the invention. Finally, it should be noted that any aspect of any of the preferred embodiments described herein can be used alone or in combination with one another.

What is claimed is:

1. A method of determining a last programmed unit of memory in a memory array comprising:
programming a set of memory cells within an array of memory cells to create a set of specially programmed memory cells, wherein each specially programmed memory cell within the set of specially programmed memory cells is programmed during a programming operation for programming a plurality of wordlines, wherein programming each specially programmed memory cell of the set of memory cells enables a last programmed wordline to be determined by a sensing operation;
performing the sensing operation across a set of strings in the memory array;
determining, based on the sensing operation, whether one or more strings failed to conduct during the sensing operation; and
determining the last programmed wordline using the one or more strings that failed to conduct.

2. The method of claim 1, wherein determining the last programmed wordline further includes counting a number of strings that failed to conduct during the sensing operation to determine the last programmed wordline.

3. The method of claim 1, wherein determining the last programmed wordline further includes identifying a memory cell associated with a highest programmed location.

4. The method of claim 1, wherein programming the set of memory cells within the array of memory cells to create a set of specially programmed memory cells includes:
programming a first set of memory cells to create a first number of specially programmed memory cells;
programming a second set of memory cells to create a second number of specially programmed memory cells, wherein the second number of specially programmed memory cells is greater than the first number of specially programmed memory cells; and
programming a third set of memory cells to create a third number of specially programmed memory cells, wherein the third number of specially programmed memory cells is greater than the second number of specially programmed memory cells.

5. The method of claim 1, wherein programming the set of memory cells within the array of memory cells to create a set of specially programmed memory cells includes:
programming a first memory cell in first row and first column of the array of memory cells comprising a plurality of rows and columns;
programming a second memory cell in a second row and second column of the array of memory cells; and
programming a third memory cell in a third row and third column of the array of memory cells.

6. The method of claim 1, wherein programming the set of memory cells within the array of memory cells to create a set of specially programmed memory cells includes:
programming a first memory cell in a first row and a first column of the array of memory cells comprising a plurality of rows and plurality of columns, wherein the first column is a leftmost column of the plurality of columns;
programming a first memory cell in a second row and the first column; and
programming a second memory cells in the second row and a second column, wherein the second column is adjacent to the first column.

7. The method of claim 6, wherein the first column is a rightmost column of the plurality of columns.

8. The method of claim 1, wherein programming the set of memory cells within the array of memory cells to create a set of specially programmed memory cells includes programming spare redundant columns.

9. The method of claim 1, programming the set of memory cells within the array of memory cells to create a set of specially programmed memory cells includes programming specifically assigned columns.

10. The method of claim 1, wherein programming the set of memory cells within the array of memory cells to create a set of specially programmed memory cells includes programming spare user columns.

11. The method of claim 1, wherein programming the set of memory cells within the array of memory cells to create a set of specially programmed memory cells includes programming any one of: spare redundant columns, specifically assigned columns, spare user columns, or any combination thereof.

12. The method of claim 1, wherein the sensing operation includes either a string sense operation or an erase sense operation, wherein the erase sense operation includes either a normal erase sense or an elevated erase sense.

13. A method of determining a last programmed unit of memory in an array of memory cells comprising:
programming a set of memory cells within the array of memory cells to create specially programmed memory cells, wherein each specially programmed memory cell within the set of memory cells is programmed along with a programming operation for programming a plurality of wordlines, and wherein each specially programmed cells is created by altering a bitline and gate voltage applied to each memory cell;
performing a sensing operation across a set of strings in the array of memory cells;
determining, based on the sensing operation, whether one or more strings failed to conduct during the sensing operation; and
determining a last programmed wordline using the one or more strings that failed to conduct.

14. The method of claim 13, wherein programming the set of memory cells within the array of memory cells to create specially programmed memory cells includes programming a memory cell to represent a plurality of wordlines.

15. The method of claim 13, wherein programming the set of memory cells within the array of memory cells to create a set specially programmed memory cells includes programming a set of memory cells within each plane of a block of memory cells.

16. The method of claim 13, wherein determining the last programmed wordline using the one or more strings that failed to conduct further includes disregarding one or more strings that conducted during the sensing operation.

17. The method of claim 13, wherein the sensing operation includes either a string sense operation or an erase sense operation, wherein the erase sense operation includes either a normal erase sense or an elevated erase sense.

18. A non-transitory computer readable storage medium storing instructions that, when executed by a processor, cause the processor to:
specially program a set of memory cells within an array of memory cells, wherein each specially programmed memory cell within the set of memory cells is specially programmed during a programming operation for programming a plurality of wordlines, wherein specially programming each memory cell of the set of memory cells enables a last programmed wordline to be determined by a sensing operation;
perform a sensing operation across a set of strings in the array of memory cells;
determine, based on the sensing operation, whether one or more strings failed to conduct during the sensing operation; and
determine the last programmed wordline using the one or more strings that failed to conduct.

19. The non-transitory computer readable storage medium of claim 18, further comprising instructions that, when executed by a processor, cause the processor to:
specially program a set of memory cells within an array of memory cells by altering a bitline voltage and gate voltage of a transistor.

20. The non-transitory computer readable storage medium of claim 18, further comprising instructions that, when executed by a processor, cause the processor to:
determine the last programmed wordline by counting a number of strings that failed to conduct.
